(19) United States
(12) Patent Application Publication
(10) Pub. No.: US 2002/0041242 A1
(43) Pub. Date: Apr. 11, 2002

(54) Semiconductor apparatus

(76) Inventors: Hideaki Takahashi, Kodaira (JP); Masayuki Sato, Takasaki (JP); Takashi Nara, Takasaki (JP)

Correspondence Address: Mattingly, Stanger & Malur, P.C., Suite 370, 1800 diagonal Road, Alexandria, VA, 22314, US

(21) Appl. No.: 09/964,483

(22) Filed: Sep. 28, 2001

(30) Foreign Application Priority Data
Oct. 2, 2000 (JP) 2000-302518

(51) Int. Cl. H03M 1/10

(52) U.S. Cl. 341/120

(57) ABSTRACT

A variable logic cell and a variable analog cell are provided in a zone on a semiconductor chip other than block formation zones of original function circuits. The variable logic cell includes a variable logic circuit for outputting a logic output, a variable wiring circuit for enabling connection of the variable logic circuit with another variable logic circuit or an analog generation circuit, and a wiring-line connection state memory circuit for storing states of switching elements of the variable wiring circuit. The variable analog cell includes an analog generation circuit having a resistive element and a capacitive element for generating a voltage, a variable wiring circuit for connecting the analog generation circuit with another analog generation circuit or variable logic circuit, and a wiring-line connection state memory circuit for storing states of the switching elements of the variable wiring circuit.

### BACKGROUND OF THE INVENTION

The present invention relates to techniques which can be effectively used in transmission of an analog signal in a semiconductor apparatus having an analog circuit built therein, and in inspection and defect relief of the analog circuit, and more particularly, to a technique which can be effectively used in a semiconductor circuit of analog/digital mixture type wherein analog and digital circuits such as D/A or A/D conversion circuits are mixed mounted on a single semiconductor chip.

For testing a semiconductor apparatus such as a logical integrated circuit (which will be referred to as the logic IC, hereinafter), there is a system which, with use of an instrument called a tester, generates and inputs test pattern data to the logic IC, and compares a data output signal of the logic IC with an expectation for judgement. However, the larger the logic scale of the logic IC is the larger the number of steps for test patterns is, which results in that it takes a lot of time to prepare such test patterns and correspondingly to conduct the tests.

As a method for facilitating the test with use of the tester, there is developed and put in practical use a test facilitating technique based on a so-called scan path design, wherein sequence circuits such as flip-flops having original IC functions are connected in cascade to enable formation of a shift register so that, upon test, test patterns are serially input (scanin) to the shift register, the test data input to the shift register is input to a desired combination of logical circuits, and thereafter an output data signal of the logical circuit combination is input to the shift register, shifted and externally extracted (scanout) therefrom.

The above scan pass method, however, has a disadvantage, when compared to a conventional test system, that the amount of test patterns can be decreased, but it is difficult to generate test patterns and to increase a failure detection rate, and that its test time is prolonged because the test patterns are repetitively input (transmitted).

In order to avoid such a disadvantage, there is developed a test technique of a built-in self test (BIST) type which builds in a logical integrated circuit a pattern generation circuit such as a pseudo random number generation circuit for generating a random test pattern. In the BIST test technique, a tester function formed by the test pattern generation circuit, a test output compression circuit, a test result judgement circuit, etc. is built in a chip of a semiconductor apparatus so that the semiconductor apparatus is tested itself to output its result as its self test.

In the BIST technique, however, upon inspection, the test circuits within the chip must be connected to an external tester to give an instruction thereto, so that less burden can be imposed on the tester but the expensive tester must wait for the inspection, whereby a cost performance cannot be decreased sufficiently. Further, an LSI having the BIST circuit built therein has other problems that its chip size is increased by an amount corresponding to the BIST circuit with an increased cost, and that a failure in the BIST circuit itself causes reduction of a yield.

A self test circuit in a semiconductor apparatus of a mixture type of an analog integrated circuit or analog circuit and a digital circuit has been studied. However, the analog test circuit often requires a resistive or capacitive element. And when such a resistive or capacitive element is formed in a process of the semiconductor apparatus, it is impossible in the state-of-the-art to obtain a highly accurate resistive or capacitive element. Thus is highly difficult to realize such a self test circuit that can test the analog circuit with a high accuracy.

### SUMMARY OF THE INVENTION

It is therefore an object of the present invention to provide a test technique which can test an analog circuit built in an LSI with a relatively high accuracy while eliminating the need for an external tester having a high level of function.

Another object of the present invention is to provide a semiconductor integrated circuit which can forms a test circuit for inspection of an analog circuit while not involving an increase in chip size.

A further object of the present invention is to provide a semiconductor integrated circuit which can form a test circuit for inspection of an analog circuit while avoiding a decrease in yield.

Yet another object of the present invention is to provide a technique which can improve a yield of a semiconductor integrated circuit having an analog circuit therein.

A still further object of the present invention is to provide a technique which can improve an operational accuracy of a semiconductor integrated circuit formed so as to transmit and receive an analog signal to and from a circuit of a chip relatively away therefrom.

The above and other objects and advantages of the present invention will become clear as the following description of the invention advances as detailed with reference to preferred embodiments of the invention as shown in accompanying drawings.

Typical ones of features of the present invention are summarized as follows.

In accordance with a first aspect of the present invention, there is provided a semiconductor apparatus which comprises an analog generation circuit including a resistive element, a capacitive element and a switching element for generating a voltage determined by a conduction time of the switching element and by a time constant of the resistive and capacitive elements based on a current flowing through the resistive element controlled by turning ON and OFF of the switching element. In the aspect, an output voltage of the analog generation circuit is transmitted to another circuit or element arranged on a semiconductor chip through a first transmission line. The voltage transmitted to the another circuit or element is fed back to the analog generation circuit through a second transmission line. The analog generation circuit generates the output voltage according to the fed-back voltage.

With the above arrangement, the analog generation circuit with a relatively simple circuit configuration can generate an arbitrary voltage. Further, even when the analog generation circuit and a circuit for receiving the output voltage of the analog generation circuit are formed on the semiconductor chip at positions relatively away from each other, the signal is transmitted in a two-line system of so-called force and sense lines so that the transmission of the highly accurate analog signal can be realized.

Desirably, the analog generation circuit can be arranged to generate an arbitrary voltage according to a pulse width of a signal for control of the switching element. Thus, only change of the pulse width of the control signal enables change of the level of the voltage to be generated. As a result, the analog voltage of an arbitrary level varying dynamically can be easily generated.

Further, the analog generation circuit is desirably a test circuit for generating a voltage for inspection of the another circuit or element arranged on the semiconductor chip. Thereby the test circuit can generate a test analog signal to be input to an analog circuit formed on the semiconductor chip without using an external expensive tester. In this connection, the analog generation circuit is a function circuit for playing a role of part of a function of the semiconductor apparatus.

Furthermore, a plurality of the analog generation circuits are provided in a zone on the semiconductor chip other than zones for formation of circuit blocks, part of the analog generation circuits is formed as a repair circuit for repairing a defect portion present in any of the function circuits taking a role of part of the functions of the semiconductor apparatus. With such an arrangement, since an LSI, which has been regarded as a defective and removed in the prior art, can be made used as an acceptable one, the LSI yield can be increased.

In accordance with a second aspect of the present invention, there is provided a semiconductor apparatus wherein a variable logic cell and a variable analog cell are provided in a zone on a semiconductor chip other than block formation zones of original function circuits. The variable logic cell includes a variable logic circuit having memory elements for outputting a logic output in response to an input according to memory information of the memory elements; a variable wiring circuit having switching elements for connecting and disconnecting a plurality of signal lines for connection of the variable logic circuit with at least another variable logic circuit and signal lines mutually intersected; and a wiring-line connection state memory circuit for storing states of the switching elements of the variable wiring circuit. The variable analog cell includes an analog generation circuit having a resistive element and a capacitive element for generating a voltage determined by a conduction time of the switching elements and by a time constant of the resistive and capacitive elements based on a current flowing through the resistive element controlled by turning ON and OFF operation of the switching elements; a variable wiring circuit for connecting or disconnecting a plurality of signal lines for connection of the analog generation circuit with at least another variable logic circuit and signal lines mutually intersected; and a wiring-line connection state memory circuit for storing states of the switching elements of the variable wiring circuit.

In a prior art logic LSI such as a system LSI having microcells such as CPU core and RAM arranged in a cell-based IC (CBIC) manner, there exist idle zones between the circuit blocks. Such idle zones amount in total to 5-10% of the chip even in average and reach nearly 20% in the worst case. When such idle zones are converted to logical gates, the number of such possible gates formable in the zones is between 40,000 and 100,000. With the above arrangement, the variable logic and analog cells provided in such idle zones can be used to form a test circuit for inspection of not only the logical circuits but also the analog circuits in the chip. As a result, a self-inspecting test circuit including the test circuit can be formed without increasing the chip size, and a semiconductor apparatus enabling acceptable or non-acceptable LSI judgement can be realized without use of an expensive tester. In addition, the above test circuit is provided within the chip, the test circuit can directly inspect target one of the circuit blocks without any intervention of another circuit block and can directly inspect even a local circuit in the circuit block. As a result, sufficient inspection can be realized even over a CPU on a chip, which has been difficult to inspect sufficiently in the prior art.

Desirably, the variable wiring circuit and wiring-line connection state memory circuit in the variable logic and analog cells have identical structures respectively, and the variable logic circuit and the analog generation circuit are formed each by elements selected from an identical group of elements formed on the semiconductor chip. As a result, the variable logic and analog cells can be easily designed. In addition, since the variable logic cell has the same dimensions as those of the analog cell, cell layout design can also be facilitated.

Further, a circuit for generating the signal for control of the switching elements is formed desirably as the variable logic cell formed on the same semiconductor chip. As a result, the analog circuit on the chip can be inspected by the test circuit formed with the cells formed in the idle zones in the chip, and the need for use of an external expensive tester can be eliminated upon inspection of the chip.

In accordance with a third aspect, there is provided a semiconductor apparatus which comprises four memory cells to be alternatively selected according to a combination of signals of positive and negative phases, and wherein a variable logic cell and a variable analog cell are provided in a zone on a semiconductor chip other than block formation zones of original function circuits. The variable logic cell includes a plurality of variable logic cells arranged to outputting signals of positive and negative phases according to memory data of the selected memory cell; a variable wiring circuit having switching elements for connecting or disconnecting a plurality of signal lines pairs for connection of the variable logic circuit with at least another variable logic circuit and signal lines mutually intersected; and a wiring-line connection state memory circuit for storing states of the switching elements of the variable wiring circuit. The variable analog cell includes an analog generation circuit having a resistive element and a capacitive element for generating a voltage determined by a conduction time of the switching elements and by a time constant of the resistive and capacitive elements based on a current flowing through the resistive element controlled by turning ON and OFF operation of the switching elements; a variable wiring circuit having switching elements for connecting or disconnecting a plurality of signal line pairs for connection of the analog generation circuit with at least another variable logic circuit and signal lines mutually intersected; and a wiring-line connection state memory circuit for storing states of the switching elements of the variable wiring circuit. With the above arrangement, the variable logic cell transmits a signal via the signal lines pairs in a differential manner, and the variable analog cell outputs a voltage generated via one of the signal lines in pair and receives a feedback voltage via the other of the signal lines in pair.

With the above arrangement, the variable logic and analog cells provided in the idle zones can be used to form a test circuit which inspects not only the logical circuit but also the analog circuit in the chip. In addition, since even the variable logic and analog cells are both connected to another cell in a two-line manner, the wiring design can be shared and the design burden can be lightened.

In accordance with a fourth aspect of the present invention, there is provided a semiconductor apparatus which comprises an analog circuit. In this case, an output voltage of the analog circuit is transmitted via a first transmission line to another circuit or element arranged on a semiconductor chip. The voltage transmitted to the another circuit or element is fed back to the analog circuit via a second transmission line. And the analog circuit generates the output voltage according to the fed-back voltage.

With the above arrangement, even when the analog generation circuit and a circuit for receiving the output voltage of the analog generation circuit are formed on the semiconductor chip at positions relatively away from each other, the signal is transmitted in a two-line system of so-called force and sense lines, so that highly accurate transmission of the analog signal can be realized.

Further, the analog circuit may be a test circuit for generating a voltage for inspection of another circuit or element arranged on the semiconductor chip, or may be a test circuit for converting to a digital signal an analog signal issued from another analog circuit arranged on the semiconductor chip.

In the semiconductor apparatus in accordance with the present invention, the variable logic and analog cells are arranged as filled on the entire semiconductor chip. After that, layout of the circuit blocks having desired functions is determined, the circuit blocks in place of the variable logic cell in the layout-determined zones on the chip are arranged to form a semiconductor apparatus. Thereafter the variable logic cells are inspected. One of the variable logic cells judged as normal is used to form a test circuit for inspection of at least one of the circuit blocks. Through the inspection, defective one of the circuit blocks can be removed.

With such an arrangement, the variable logic and analog cells remaining between the arranged circuit blocks are inspected, and cells judged as normal are used to form a test circuit for inspection of the circuit blocks. As a result, there can be realized a semiconductor apparatus which can form a test circuit which can perform self inspection without increasing the chip size, and a decrease in yield caused by defect generation in the test circuit can be avoided.

After the circuit blocks are inspected by the test circuit formed with the variable logic cell, the semiconductor apparatus determined as defective based on the inspection result may be removed, and the logical circuit or analog circuit having functions desired by the user may be formed with use of the variable logic and analog cells so far formed in the test circuit. As a result, there can be realized a semiconductor apparatus with less overhead.

### BRIEF DESCRIPTION OF THE DRAWINGS

FIG. 1 is a block diagram of a system LSI having an A/D conversion circuit built therein in accordance with an embodiment of the present invention;

FIG. 2 is a circuit configuration of an example of a voltage generation circuit for generating a test voltage for the A/D conversion circuit provided within the system LSI of the present invention;

FIG. 3 is a schematic circuit of a two-line type for transmission of analog signals;

FIG. 4 is a block diagram of a system LSI having a D/A conversion circuit built therein in accordance with an embodiment of the present invention;

FIG. 5 is a circuit configuration of an example of a voltage measurement circuit for generating a test voltage for the D/A conversion circuit provided within the system LSI of the present invention;

FIG. 6 is a flowchart showing an exemplary inspection procedure of an internal circuit in the system LSI of the present invention;

FIG. 7 is a circuit diagram of an example of a variable logical circuit used in a semiconductor integrated circuit in the present invention;

FIG. 8 is a diagram for explaining the concept of the variable logical circuit in the example of FIG. 7;

FIG. 9 is a schematic circuit diagram of an example of a variable wiring circuit which includes signal lines and switching elements to be connected between arbitrary variable logical circuits;

FIG. 10 is a circuit diagram of a specific example of variable logical cells formed as a field programmable logic array (FPLA);

FIG. 11 is a block diagram of an exemplary configuration of a write system circuit to logic setting memory cells in the FPLA having the variable logical cells arranged therein and to memory cells of a wiring connection information memory circuit forming the variable wiring circuit in the example;

FIG. 12 is a logical arrangement of an example of input/output system circuits with respect to the logical circuit on the FPLA having the variable logical cells of the example arranged therein;

FIG. 13 is a layout of a system LSI in accordance with another embodiment of the present invention, showing how circuit blocks are arranged in the FPLA having variable logical cells and variable analog cells filled as arranged therein;

FIG. 14 is a flowchart for explaining a procedure ranging from design to manufacture of a semiconductor integrated circuit with the FPLA having the variable logical cells and variable analog cells filled and arranged therein;

FIG. 15 is a schematic configuration of an example of variable analog cells (for the voltage generation circuit) formed in the FPLA;

FIG. 16 is a schematic configuration of an example of variable analog cells (for the voltage measurement circuit) formed in the FPLA;

FIG. 17 is a schematic configuration of a specific example of the variable analog cells of FIG. 15;

FIG. 18 is a schematic configuration of a specific example of the variable analog cells of FIG. 16;

FIG. 19 is a schematic configuration of another example of wiring connection in the FPLA;

FIG. 20 is a circuit diagram of an exemplary configuration of the FPLA including the variable logical cells and variable analog cells;

FIG. 21 is a circuit diagram showing an example of a wiring formation method for wiring the variable logical cells and variable analog cells in the system LSI of the present invention;

FIG. 22 is a circuit diagram showing an example of connection between a test circuit of the variable analog cells in the system LSI of the invention and a circuit to be tested;

FIG. 23 is a diagram for explaining how circuit blocks are arranged in the FPLA and how defective one of the blocks is replaced with a circuit formed as an FPLA in another embodiment of the system LSI of the present invention;

FIG. 24 is a diagram for explaining how circuit blocks are arranged in the FPLA in another embodiment of the system LSI of the present invention;

FIG. 25 is a block diagram of an example of a circuit for processing a read signal from a magnetic storage medium and generating a write signal in a PRML manner;

FIG. 26 is a diagram for explaining a relationship between the circuit of FIG. 25 and the test circuit formed in the FPLA; and

FIG. 27 is a layout of an embodiment to which the present invention is applied.

### DESCRIPTION OF THE EMBODIMENTS

The present invention will be explained in connection with preferred embodiments with reference to the accompanying drawings.

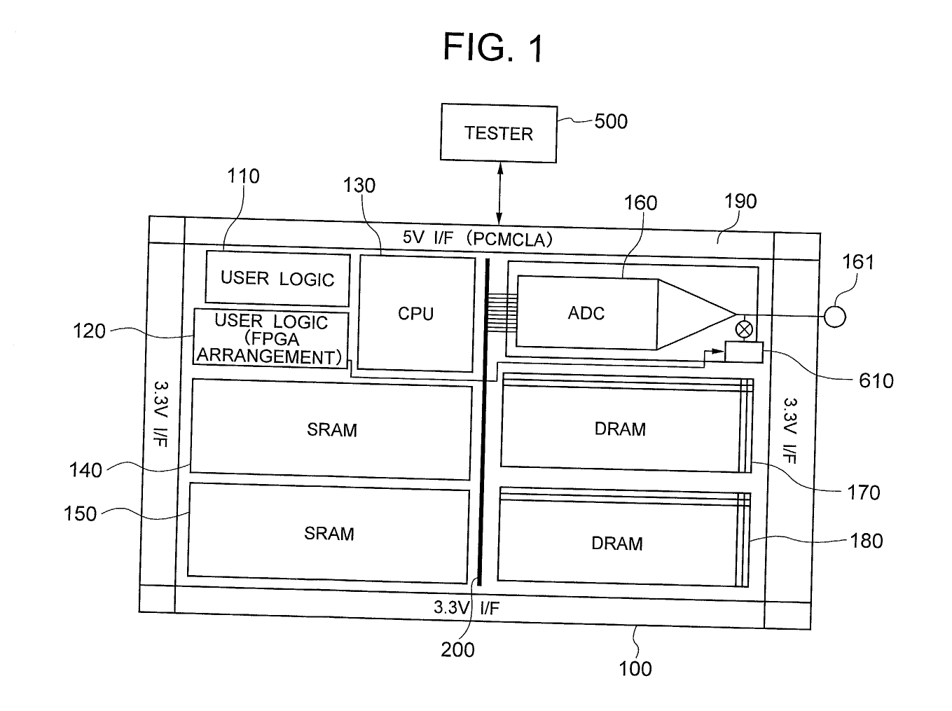

FIG. 1 is a block diagram of a system LSI having an A/D conversion circuit built therein in accordance with an embodiment of the present invention, which is formed on a semiconductor chip 100 such as a single crystal silicon by a known technique for manufacturing a semiconductor apparatus.

In FIG. 1, reference numerals 110 to 180 denote internal circuits formed on the semiconductor chip 100, reference numeral 190 denotes an interface circuit for input and output of a signal between the internal circuits and an external device, and numeral 200 denotes an internal bus for connection between the internal circuits 110 to 180 and between the internal circuits and interface circuit 190. Among the internal circuits 110 to 180, the internal circuits 110 and 120 are custom logical circuits such as user logical circuits having logical functions demanded by a user. The internal circuit 120 is formed in the form of a field programmable gate array (FPGA) whose logic can be formed by the user. The custom logical circuit may remain as it is without forming the user logic.

Reference numeral 130 denotes a central processing unit (CPU) for decoding an instruction in a program and performing corresponding operation or calculation, numerals 140 and 150 denote static random access memories (RAM's), 160 denotes an A/D conversion circuit, 170 and 180 denote dynamic RAM's. Further provided in a peripheral edge part of the system LSI of this embodiment is the interface circuit 190 which inputs and outputs a signal to and from an external tester 500 or the like in an internal circuit test mode. The tester 500 is not required to have a high level of function as in a conventional logical LSI or memory tester, but may be a test which can perform data writing/reading operation and simple data processing operation, that is, may be a personal computer.

The CPU 130 may be a microprocessor which includes, in addition to a CPU called in a narrow sense, so-called microcomputer peripheral circuits such as a program ROM, a working RAM, a serial communication interface and a timer circuit.

The above static RAM's 140, 150 and dynamic RAM's 170, 180 include a memory peripheral circuit which selects corresponding one of memory cells when an address signal is given via the internal bus 200. Further, the dynamic RAM's 170 and 180 include a refresh control circuit which performs periodical pseudo selection in such a manner that, even when a non-access time becomes long, information charge of the memory cell will not be lost. The dynamic RAM's 170 and 180 have respectively a so-called redundancy circuit which, when a defect bit is present in a memory array, replaces a memory row or column containing the defect bit with a preliminary memory row or column, although not specifically restricted to it.

Further, the A/D conversion circuit 160 in the present embodiment has a voltage generation circuit 610 which generates a test analog voltage in such a manner that the voltage generated by the voltage generation circuit 610 in place of an analog input voltage from an external input terminal 161 can be input to the A/D conversion circuit 160.

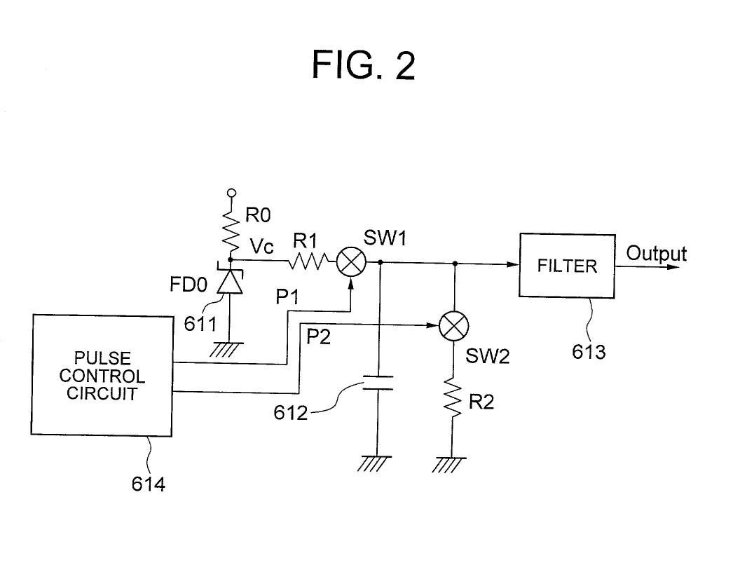

FIG. 2 shows a specific example of the voltage generation circuit 610 provided in the A/D conversion circuit 160 among the internal circuits 110 to 180 shown in FIG. 1.

The voltage generation circuit 610 in the present embodiment includes a constant voltage circuit 611 having a resistor R0 and a Zener diode D0 connected in series for generating a predetermined voltage Vc, a capacitor 612 connected at one terminal to a constant potential point such as a grounding point for charging or discharging electric charge, a switch SWI and a resistor R1 connected in series between the other terminal of the capacitor 612 and the constant voltage circuit 611, a switch SW2 and a resistor R2 connected in series between the other terminal of the capacitor 612 and the grounding point, and a filter circuit 613 for smoothing a voltage charged in the capacitor 612.

The voltage generation circuit 610 generates a voltage determined by a ratio between the resistors R1 and R2, the periods and pulse widths of the control pulses P1 and P2, and the predetermined voltage Vc from the constant voltage circuit 611, when the switches SW1 and SW2 are turned ON and OFF by control pulses P1 and P2 from a pulse control circuit 614. That is, the control pulses P1 and P2 are set so that their high level durations are not overlapped with each other. Thus when the switch SW1 is turned ON by the control pulse P1, the switch SW2 is turned OFF, so that electric charge is gradually charged in the capacitor 612 via the resistor R1. When the switch SW2 is turned ON by the control pulse P2, the switch SW1 is turned OFF, so that the electric charge of the capacitor 612 is gradually discharged via the resistor R2.

Through the repetition of the above operation, the charge voltage of the capacitor 612 is changed to a saw tooth wave shape and smoothed by the filter circuit 613 into a desired voltage corresponding to the control pulses P1 and P2. When the voltage is supplied to the A/D conversion circuit 160, the A/D conversion circuit 160 can be tested without receiving an external analog voltage. In addition, the voltage generation circuit 610 in the present embodiment can generate a desired voltage or waveform by changing the periods and pulse widths of the control pulses P1 and P2.

Even when the resistive values of the resistors R1 and R2 vary in process, the ratio between the resistors becomes substantially constant. Even when the capacitive value of the capacitor 612 varies, the identical capacitor is used for the charging and discharging operations. As a result, the voltage generated by the semiconductor apparatus is less affected by such variations. In addition, since the voltage generation circuit 610 is disposed in the vicinity of the A/D conversion circuit 160 to which the generated voltage is supplied, the input voltage of the A/D conversion circuit 160 can be increased in accuracy in a test mode. In this connection, the voltage generation circuit 610 is not limited to having such an arrangement as shown in FIG. 2, but may employ one of various other arrangements. For example, when the resistors R1 and R 2 are replaced with resistive components of the switches SW1 and SW2, the resistors R1 and R2 can be omitted.

The present embodiment, on the other hand, is arranged so that the pulse control circuit 614 for generating the control pulses P1 and P2 for turning ON and OFF of the switches SW1 and SW2 is provided on the FPGA 120 prior to formation of a custom logic. A circuit for judging a digital signal as the output of the A/D conversion circuit after converting the voltage generated by the voltage generation circuit 610 is also provided on the FPGA 120. However, in place of the provision of the exclusive judgement circuit, such an arrangement may be employed that the built-in CPU 130 judges the digital signal and externally outputs its judged result through the interface circuit 190.

The control pulses P1 and P2 supplied to the voltage generation circuit 610 are digital signals. Thus, even when the pulse control circuit 614 for generating the control pulses P1 and P2 is positioned away from the voltage generation circuit 610, the accuracy will not be decreased by the pulse transmission. Although the voltage generation circuit 610 for generating a test analog voltage has been provided in the A/D conversion circuit 160 in the embodiment of FIG. 1, the voltage generation circuit 610 may be provided in an idle space between the A/D conversion circuit 160 and another external circuit block.

In this way, when the voltage generation circuit 610 is provided at a location relatively away from the analog input terminal regardless of the provision of the circuit 610 inside or outside of the A/D conversion circuit 160, the resistance, etc. of a wiring line for transmission of the generated voltage (analog signal) up to the analog input terminal may cause accuracy reduction of the voltage level. To avoid this, in the present embodiment, the accuracy reduction of the voltage level can be prevented by employing a two-line system of force and sense lines (which will be explained later). With it, the voltage generation circuit 610 can be located in a position relatively away from the A/D conversion circuit 160, e.g., in the vicinity of the custom logical circuit 120 in the embodiment of FIG. 1.

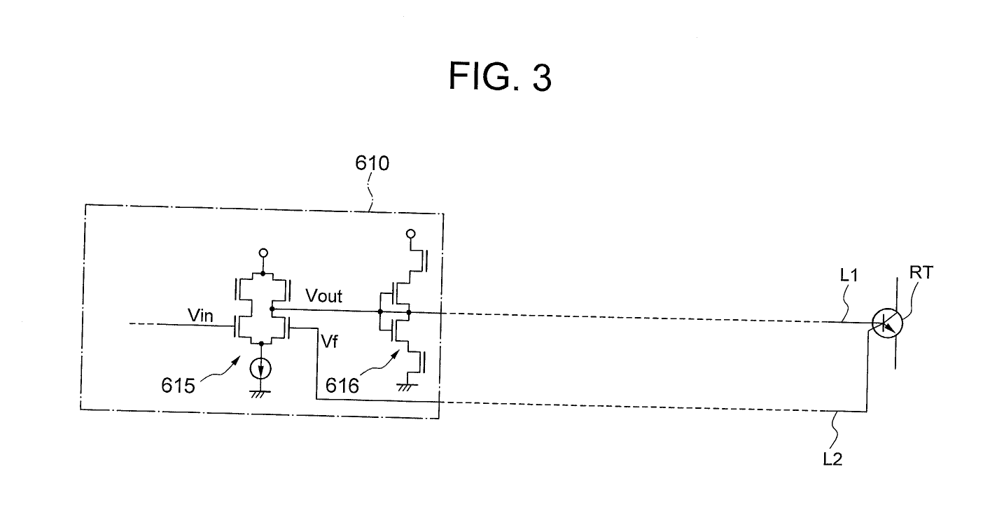

In the two-line system of the force and sense lines, as shown in FIG. 3, a differential amplification circuit 615 is provided upstream of a final output stage 616 of a circuit (voltage generation circuit 610 in FIG. 1) for outputting an analog signal. A transmission line L1 extended from the voltage generation circuit 610 to a circuit or element (bipolar transistor RT in FIG. 3) as a target of the above output analog signal will be referred to as the force line. A feedback line L2, which is extended parallel to the force line and acts to feed a voltage at an end of the force line back to the differential amplification circuit 615 of the start circuit 610, will be referred to as the sense line. In this connection, the final output stage 616 is a circuit equivalent to a voltage follower which outputs a voltage having the same level as its input voltage.

When a circuit for outputting an analog signal is located at a position relatively away from a circuit for receiving the analog signal and the receiver-side circuit has a relatively small input impedance, a voltage drop across a transmission line caused by its line resistance becomes as large as unnegligible and the operational accuracy of the circuit drops. When the above two-line system is employed, however, such accuracy drop can be avoided. That is, when the force and sense lines are provided as shown in FIG. 3, even a voltage drop across the transmission line L1 for transmission of the analog signal causes the voltage drop to be fed back to the differential amplification circuit 615 through the sense line L2, which results in that the differential amplification circuit 615 is operated so that the feedback voltage coincides with an input voltage Vin due to its inherent property of the circuit.

As will be clear by referring to the circuit of FIG. 3, since the differential amplification circuit 615 is made up of an MOS FET, the circuit has a relatively high input impedance and thus a drop of a voltage Vf fed back through the sense line L2 becomes as very small in level as negligible. As a result, an output voltage Vout is higher by an amount corresponding to the voltage drop of the force line L1 than the input voltage Vin so that a voltage at an end of the force line L1 of the force line L1 has the same level as the input voltage Vin of the differential amplification circuit 615, thus realizing right transmission of the analog signal.

Although the differential amplification circuit 615 has been made up of the MOS FET in the example of FIG. 3, it may comprise a bipolar transistor. When the differential amplification circuit 615 is made up of a bipolar transistor, the differential amplification circuit 615 has a small input impedance and thus a current flows even through the sense line L2, developing a voltage drop thereacross. However, this can be avoided by designing the final output stage 616 in such a manner as to output a higher voltage previously by an amount corresponding to the voltage drop of the force line L1. In this connection, the final output stage 616 may be omitted and the voltage may be directly output from the differential amplification circuit 615. Further, the final output stage 616 may comprise a voltage follower using a differential amplifier.

When the force line L1 and sense line L2 are previously designed to be parallel to each other and to pass the same current therethrough, the voltage drop across the force line L1 becomes substantially equal to that of the sense line L2. Thus when the final output stage 616 is arranged to output a voltage higher than the input voltage Vin of the differential amplification circuit 615 by an amount corresponding to half of a difference between the input voltage Vin and the feedback voltage Vf from the sense line L2, such a circuit as to output a voltage ensuring the voltage drop of the force line L1 can be designed relatively easily.

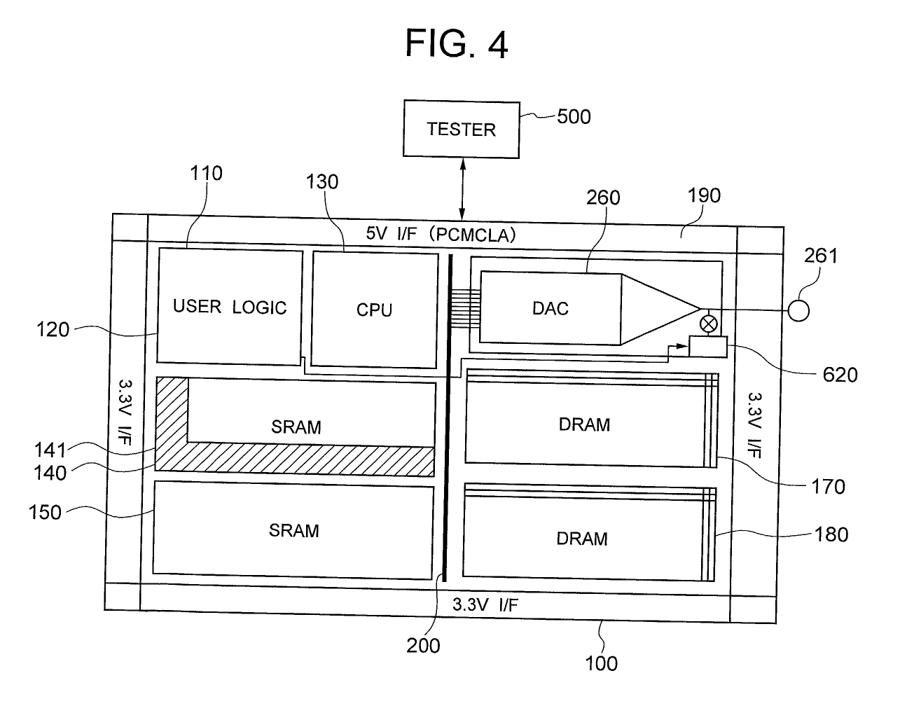

FIG. 4 is a block diagram of a system LSI having a D/A conversion circuit built therein in accordance with another embodiment of the present invention.

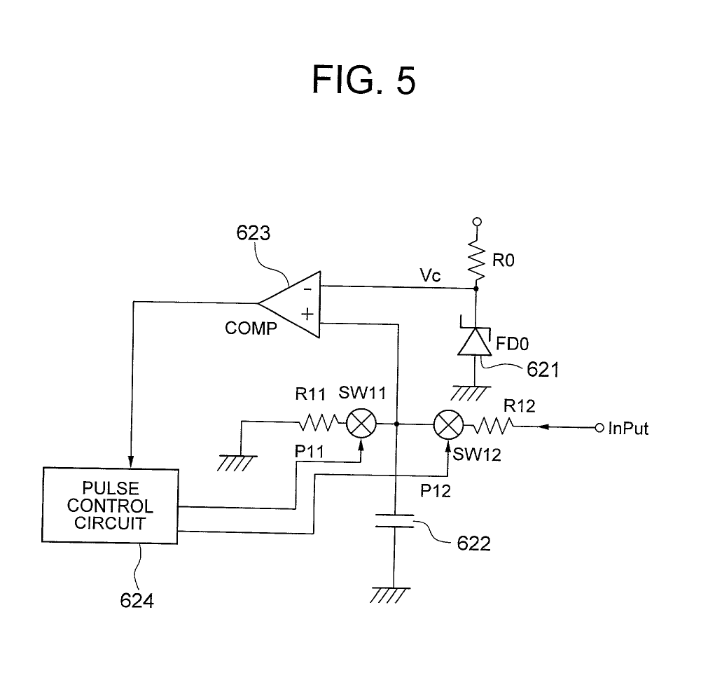

In FIG. 4, reference numeral 260 denotes a D/A conversion circuit 260, and numeral 620 denotes a voltage measurement circuit which is provided in the D/A conversion circuit 260 to convert an analog output voltage to a digital signal that is output from the D/A conversion circuit 260 to an external output terminal 261. Shown in FIG. 5 is an example of the voltage measurement circuit 620.

The voltage measurement circuit 620 of the example includes a constant voltage circuit 621 having a resistor R0 and a Zener diode D0 connected in series for generating a predetermined voltage Vc, a capacitor 622 connected at its one terminal to a constant potential point such as a grounding point for charging and discharging electric charge, a switch SW11 and a resistor R11 connected in series between the other terminal of the capacitor 622 and an input voltage Vin, a switch SW12 and a resistor R12 connected in series between the other terminal of the capacitor 622 and the grounding point, a comparator 623 made up of, e.g., a differential amplification circuit for comparing a charged voltage of the capacitor 622 with a constant voltage of the constant voltage circuit 621, and a pulse control circuit 624 for generating control pulses P11 and P12 for ON and OFF control of the switches SW11 and SW12.

The voltage measurement circuit 620 is set so that high level durations of the control pulses P11 and P12 are not overlapped with each other. When the switch SW12 is first turned ON by the control pulse P12 received from the pulse control circuit 624 to cause the capacitor 622 to sample an input voltage. Next the control pulse P11 is given to the switch SW11 to draw electric charge from the capacitor 622. The comparator 623 compares the then charge voltage, i.e., the voltage Vc of a node N2 with the constant voltage of the constant voltage circuit 621.

The control pulse P11 is previously set to be shorter than the control pulse P12 or the value of the resistor R12 is previously set to be smaller than that of the resistor R11 to allow high-speed charging and gradual discharging. Under the above conditions, after the charged condition, the ON and OFF operation of the switch SW11 is repeated to gradually lower the voltage of the capacitor 622 and to count the number of pulses in the control pulse signal P11 until the output of the comparator 623 is inverted. When the number of pulses, pulse widths of the control pulses P11 and P12, and a ratio between the resistors R11 and R12 are calculated, the value of the input voltage first sampled by the capacitor 622 can be known.

In this example, the pulse control circuit 624, counter for counting the above pulse number, the calculation circuit, the circuit for generating a digital signal (test pattern) to be applied to the D/A conversion circuit 260, etc. are made in the form of a field programmable logic array (FPLA) 141 (which will be explained later) provided in the SRAM 140 for test of the D/A conversion circuit 260. Therefore, with use of the voltage measurement circuit 620 of the example, the D/A conversion circuit 260 can be tested while eliminating the need for an external tester to measure an analog voltage output from the D/A conversion circuit 260 to the external output terminal 261. However, in the case of the LSI having the custom logical circuit of the FPGA as a user logic as in the embodiment of FIG. 1, the above pulse control circuit 624, counter, calculation circuit, etc. may be formed in the FPGA before formation of the user logic.

The voltage measurement circuit 620 of this example can measure a voltage with any level of accuracy by changing the periods and pulse widths of the control pulses P11 and P12. Further, in the case of the semiconductor apparatus, even when the resistive values of the resistors R11 and R12 vary in the process, the ratio between the resistors becomes substantially constant. And even when the capacitive value of the capacitor 622 varies, the voltage measuring accuracy is less affected by the variation because the same capacitor is used for both the charging and discharging operations. In addition, the voltage measurement circuit 620 is disposed in the vicinity of the D/A conversion circuit 260 for outputting a voltage to be measured, the measurement accuracy of the output voltage of the D/A conversion circuit 260 can be improved in the test mode.

Since the control pulses P11 and P12 supplied to the voltage measurement circuit 620 are of digital signals, even when the pulse control circuit 624 for generating the control pulses P11 and P12 is formed within the field programmable logic array (FPLA) 141 positioned away from the voltage measurement circuit 620, the accuracy drop will not take place. Even in this embodiment, the voltage measurement circuit 620 may be provided in an idle space between the D/A conversion circuit 260 and another external circuit block or at a position away therefrom. And even in such a case, when the analog signal transmission system of the two-line type of force and sense lines is employed, measurement can be carried out with a high accuracy even when the D/A conversion circuit 260 and voltage measurement circuit 620 are formed located relatively away from each other.

In this connection, the voltage measurement circuit 620 is not limited to the arrangement of the example of FIG. 5 but may have one of various sorts of arrangements. For example, the resistors R11 and R12 may be omitted when resistive components of the switches SW11 and SW12 are used as the resistors R11 and R12.

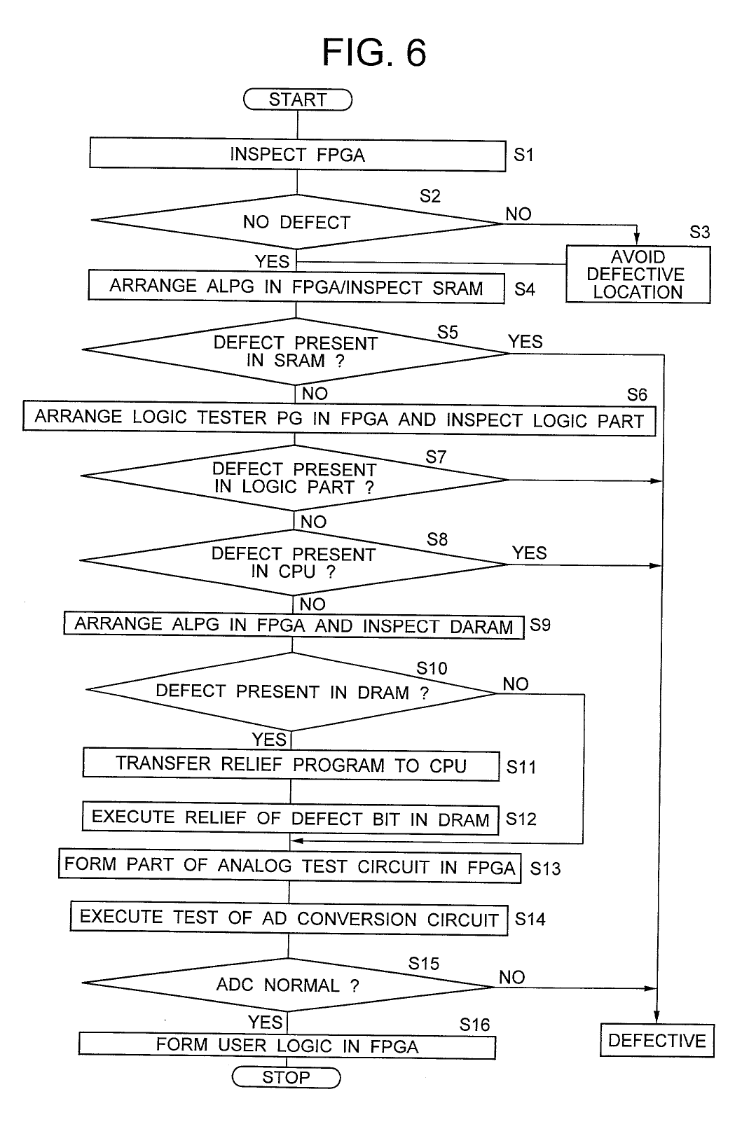

Explanation will next be made as to an example of a method for testing the entire system LSI of FIG. 1 having the A/D conversion circuit built therein, by referring to FIG. 6.

In the test of the LSI of FIG. 1, the system first examines whether or not the FPGA 120 normally operates for judgement of presence or absence of a defect. When judging the presence of a defect, the system avoids the defect portion (steps S1 to S3). For a portion of the FPGA 120 other than the defect portion, the system forms a test circuit (ALPG): Algorithm Pattern Generator) for testing the SRAM's 140 and 150, and the system sequentially tests the SRAM's 140 and 150 (steps S4 and S5).

When failing to find a defect portion in the SRAM's 140 and 150, the system forms a test circuit (logic tester) for testing the custom logical circuit 110 and CPU 130 in the portion of the FPGA 120 other than the above defect portion, and sequentially performs testing operations over the custom logical circuit 110 and CPU 130 (steps S6 to S8). At this time, the system stores test pattern or a test pattern generating program in the already-inspected SRAM.

When failing to find a defect, the system forms a test circuit (ALPG) for testing the DRAM's 170 and 180 in the portion of the FPGA 120 other than the above defect portion, and sequentially performs testing operations over the dynamic RAM's 170 and 180 (steps S9 and S10). And when finding a defect portion, the system stores the defect portion in the SRAM 140 or 150 or in an external storage, and then reads a defect relief program into the CPU 130 for utilizing the redundancy circuits provided in the DRAM's 170 and 180 to cause the CPU 130 to execute the program for bit relief (steps S11 and S12).

Thereafter the system forms, in the portion of the FPGA 120 other than the defect portion, an analog test circuit which generates an expectation of the digital output signals for the pulse control circuit 614 which supplies the control pulse to the voltage generation circuit 610 for test of the A/D conversion circuit 160 to generate an analog voltage, and for the A/D conversion circuit 160 and compares the expectation with data after analog/digital conversion to judge whether or not a desired accuracy was obtained (step S13). In the step S13, the system, by utilizing information indicative of the defect portion obtained in the step S1, generates data to avoid the defect portion and to form the analog test circuit containing the pulse control circuit 614 in the FPGA 120, and writes the data to the memory cells for connection information storage in the FPGA 120 to thereby form a circuit having a desired function.

Subsequently the system activates the analog test circuit containing the pulse control circuit 614 formed in the FPGA 120, sends the control pulse to the voltage generation circuit 610 to generate an analog voltage, converts the voltage to a digital voltage at the A/D conversion circuit 160 to execute the test (step S14). And the system compares the converted digital data with the expectation to judge the LSI having a desired accuracy and performance as acceptable and the LSI not having the desired accuracy and performance as unacceptable (step S15).

For the acceptable LSI, the system forms part of the custom logic such as user logic in the portion of the FPGA 120 other than the defect portion to complete a system LSI (S16). In the step S16, the system, by utilizing the information indicative of the defect portion obtained in the step S1, writes data forming the user logic in the memory cells for connection information storage within the FPGA 120 to avoid the defect portion and to form a desired logic.

In this manner, a system LSI having a desired function is formed. For the LSI formed in this manner, since the RAM, DRAM, CPU and A/D conversion circuit of the LSI are already tested by the test circuit formed in the FPGA 120 so as to avoid the defect portion, a reliable test result can be obtained without use of an external tester having a high level of function and thus a yield of the LSI can be improved. In addition, since the A/D conversion circuit can be tested accurately only by forming the voltage generation circuit 610 as a part of the test circuit for the A/D conversion circuit in the A/D conversion circuit 160, an increase in chip size caused by building the test circuit in the LSI can be avoided. Further, after the LSI is self tested by the test circuit formed in the FPGA 120, the custom logic is formed in the FPGA 120. Thus unnecessary circuits can be minimized and an extra increase in the chip size can be suppressed.

How to test the entire LSI in the system LSI of FIG. 4 having the D/A conversion circuit built therein is substantially the same as the step S4 and subsequent steps in the flowchart of FIG. 6. Different points therebetween are that the ALPG forming the FPGA and the test circuit are formed not in FPGA but in part of the SRAM 140 in the steps S4, S6, S9 and S13, and that the circuit to be tested in the steps S13 to S15 is not the A/D conversion circuit but the D/A conversion circuit.

Even in the LSI of FIG. 4, the RAM, DRAM, CPU and D/A conversion circuit are tested by the test circuit formed in the field programmable logic array 141. Thus a highly reliable test result can be obtained without using an external tester having a high level of function and therefore a yield can be improved. Further, since the D/A conversion circuit can be tested with a high accuracy only by forming the voltage measurement circuit 620 forming a part of the test circuit of the D/A conversion circuit 260 in the D/A conversion circuit 260, an increase in the chip size involved by the built-in test circuit can be avoided. Further after the LSI is self tested by the test circuit formed in the field programmable logic array 141, the array 141 can be used as an SRAM, with the result that wasteful circuits can be minimized and an extra increase in the chip size can be suppressed.

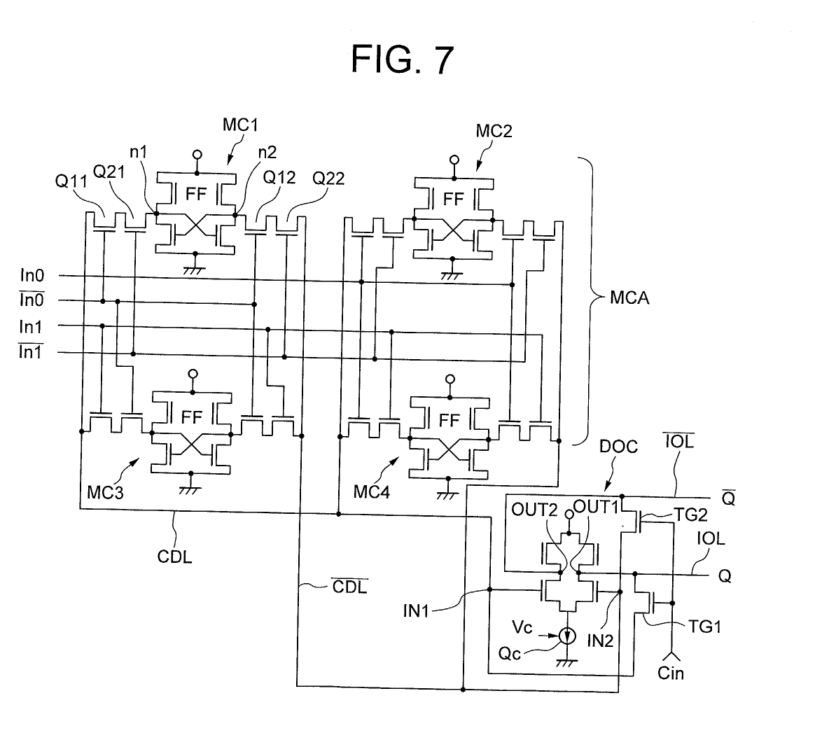

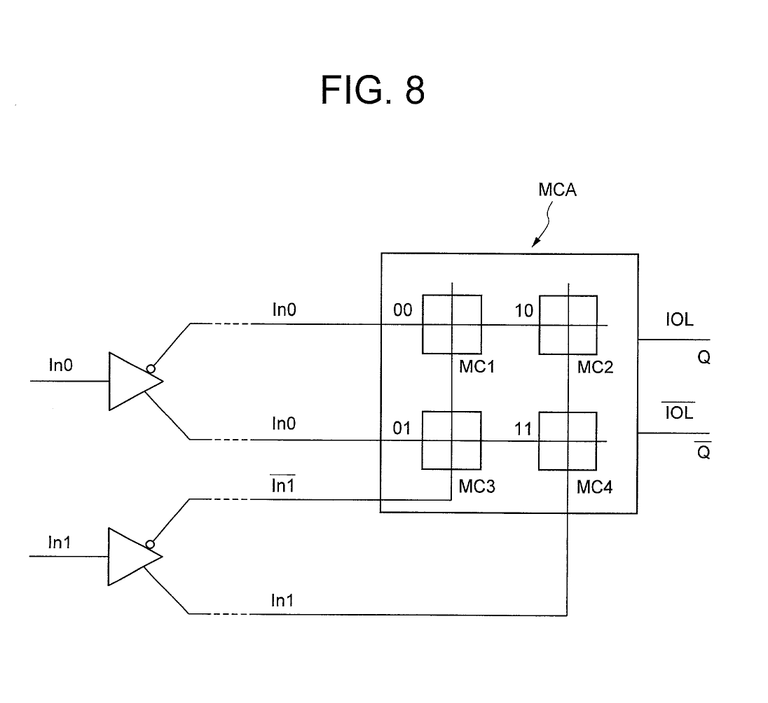

Explanation will then be made in connection with a specific example of the field programmable logic array 141. FIG. 7 is an example of the variable logic circuit forming the field programmable logic array 141, and FIG. 8 is a diagram for explaining its concept. The variable logic circuit of FIG. 7 is a two-input logical circuit which has four memory cells and one complementary output circuit. In FIG. 7, MC1, MC2, MC3 and MC4 denote memory cells having substantially the same structure as the memory cells forming a known SRAM (static random access memory), DOC denotes a data output circuit as a differential amplification circuit, TG1 and TG2 denote input transmission gates for supplying write data to the memory cells MC1 to MC4. And the circuit of FIG. 7 is arranged so that signals corresponding to word select signals in an ordinary SRAM are supplied to a memory array MCA of the four memory cells MC1 to MC4 for logic setting as differential input signals In0, /In0, In1, and /In1.

In this way, when differential signals are used as the input signals of the memory array MCA, a logical circuit immune to noise can be realized even when the reduced voltage of the semiconductor apparatus causes the signal level to become small. As a result, a decoder for selecting one of the memory cells MC1 to MC4 can be made unnecessary. When the variable logic circuit in question is of a type which receives a signal directly from the external terminal, output signals of buffers BFF0 and BFF1 for converting input signals In0 and In1 to signals of positive and negative phases are supplied to the memory array MCA as shown in FIG. 8. When the variable logic circuit in question is of a type which inputs signals from another variable logic circuit, on the other hand, the differential signals issued from the other variable logic circuit having substantially the same structure as FIG. 7 are input as they are.

The memory cells MC1 to MC4 forming the variable logic circuit of the present embodiment are different from memory cells forming a known SRAM in that each of the SRAM memory cells has a pair of selecting MOS FET's, whereas, each of the memory cells in the present embodiment has two pairs of selecting MOS FET's. That is, each of the memory cells MC1 to MC4 forming the variable logic circuit of the present embodiment includes a flip-flop circuit FF having two inverters cross-connected at their input and output terminals, and selecting MOS FET's Qs11, Qs12, Qs21 and Qs22 connected respectively in series with two input and output nodes n1 and n2.

The flip-flop circuit FF may comprise two CMOS inverters of P-channel and N-channel type MOS FET's cross-connected at their input and output terminals. Or the flip-flop circuit FF may comprise two inverters of an N-channel type MOS FET and a depletion type MOS FET or a polysilicon resistor connected to a power voltage Vcc of the N-channel type MOS FET, the inverters being cross connected at their input and output terminals.

In the variable logic circuit of the present embodiment, any of combination signals (In0, In1; In0, /In1; In0, In1; and /In0, /In1) of the input signals In0 or /In and In1 or /In1, are applied to gate terminals of the selecting MOS FET's Qs11, Qs12 and Qs21, Qs22 of the four memory cells MC1 to MC4. And the input and output nodes n1 and n2 of the flip-flop circuits FF's of the memory cells MC1 to MC4 are connected via the MOS FET's Qs11, Qs12 and Qs21, Qs22 to common data signal lines CDL and /CDL which in turn are connected at their ends with a pair of input nodes IN1 and IN2 of the data output circuit DOC respectively.

Also connected between input and output signal lines IOL and /IOL connected to the common data signal lines CDL and /CDL and to the output nodes OUT1 and OUT2 of the data output circuit DOC are input transmission gates TG1 and TG2 of MOS FET's, to gate terminals of which a common input control signal Cin is applied. The input transmission gates TG1 and TG2 are not limited to MOS FET's and each may comprise, for example, a logical gate circuit such as an AND gate. The data output circuit DOC is also not limited to such a differential amplification circuit as shown in FIG. 7. When the data output circuit DOC is made up of such a differential amplification circuit as shown in FIG. 7, an MOS FET Qc of a constant current type is desirably arranged so that, in a data input mode where the input transmission gates TG1 and TG2 are put in a conduction mode by the input control signal Cin, a current flowing through the MOS FET Qc is interrupted, e.g., by lowering a gate bias voltage Vc to 0V.

Explanation will next be made as to the operation of the variable logic circuit of the present embodiment and how to use it. In the variable logic circuit of the present embodiment, as shown in FIG. 8 and Table 1, the four memory cells MC1 to MC4 use any of two sets of differential signals In0, /In0; and In1, /In1 as select signals, and when one of the memory cells having the two signals both with a high level, the memory cell can be regarded as a selected one.

TABLE 1

| | | Selected memory |
|---|---|---|
| In0 | In1 | cell |
| 0 | 0 | MC1 |
| 1 | 0 | MC2 |
| 0 | 1 | MC3 |
| 1 | 1 | MC4 |

Thus, when data are previously written in the memory cells MC1 to MC4 as shown in Table 2 given below, output signals of the memory cells MC1 to MC4 in response to the two input signals In0 and In1 correspond to NAND logic, AND logic, OR logic, exclusive OR (EOR), NOR logic or exclusive NOR (ENOR) of the input signals In0 and In1.

In other words, the variable logic circuit of the present embodiment can realize the function of basic logical gate circuit necessary for forming the logic of the logic LSI by suitably setting the data to be written to the four memory cells MC1 to MC4. Accordingly, by disposing a multiplicity of such variable logic circuits as dispersed on a semiconductor chip and by providing on the chip a field programmable wiring circuit including a group of wiring lines for connection between the variable logic circuits and switching elements at intersections of signal lines; a field programmable logic array (which will be referred to as FPLA, hereinafter) can be realized.

TABLE 2

| | | | | Logic |
|---|---|---|---|---|
| MC1 | MC2 | MC3 | MC4 | output |
| 1 | 1 | 1 | 0 | NAND |
| 0 | 0 | 0 | 1 | AND |
| 0 | 1 | 1 | 1 | OR |
| 0 | 1 | 1 | 0 | EOR |
| 1 | 0 | 0 | 0 | NOR |
| 1 | 0 | 0 | 1 | ENOR |

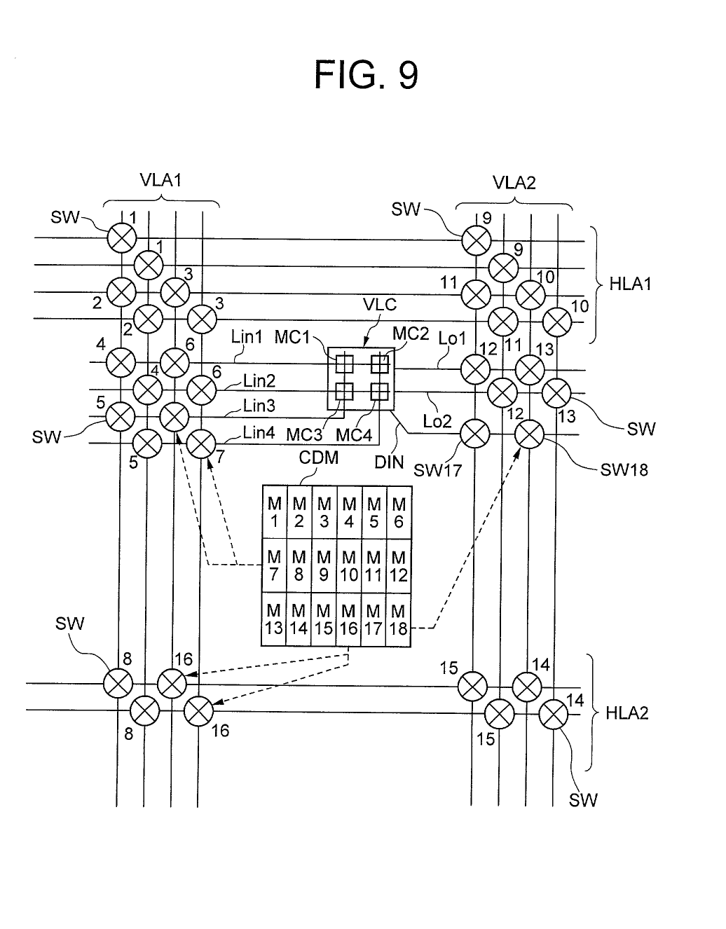

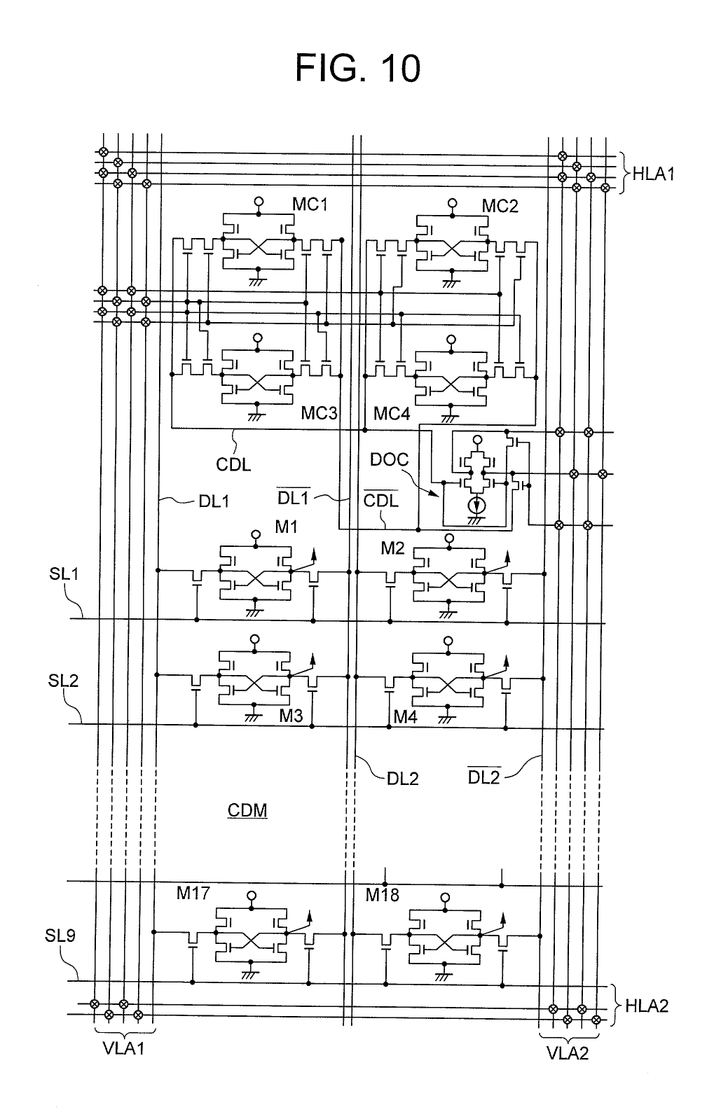

By referring to FIGS. 9 and 10, explanation will then be made in connection with a specific example of the field programmable wiring circuit enabling interconnection between any ones of the variable logic circuits when it is desired to form an FPLA having a plurality of variable logic circuits of FIG. 7 mounted on a semiconductor chip.

As shown in FIG. 9, grid-like wiring zones VLA and HLA are provided on a chip, the variable logic circuit (memory cells MC1 to MC4 and data output circuit DOC) VLC of the above embodiment and a wiring connection information storage circuit CDM are disposed in a rectangular zone defined by the wiring zones VLA and HLA. Each of the vertical wiring zones VLA1 and VLA2 has four signal lines, each of the horizontal wiring zones HLA1 and HLA2 has four signal lines, switching elements SW enabling electrical connection between the vertical and horizontal signal lines are provided at intersection points between the vertical and horizontal wiring zones VLA and HLA, though the number of such lines is not specifically limited to the shown example.

Further at intersection points between input signal lines Lin1 to Lin4 of the variable logic circuit VLC and the vertical signal lines VLA1, and at intersection points between output signal lines Lo1 and Lo2 of the variable logic circuit VLC and the vertical signal lines VLA2, such switching elements SW enabling electrical connection between these signal lines are provided. The number of such switching elements SW provided for one variable logic circuit is 34 in the present embodiment, though not specifically limited to the specific value. Such a circuit arranged with the switching elements SW enabling electric connection between the variable logic circuit VLC, wiring connection information storage circuit CDM, wiring zones HLA1, HLA2 and vertical and horizontal signal lines as shown in FIG. 9, will be referred to as the variable logic cell LCL.

The wiring connection information storage circuit CDM is made up of 18 memory cells each having a similar structure to the SRAM memory cell, the switching elements SW are associated with any of the 18 memory cells in the wiring connection information storage circuit CDM and are put in its ON or OFF state depending on wiring connection information stored in the associated memory cells.

In the present embodiment, since each variable logic circuit VLC receives two input signals (differential signals) of positive and negative phases and similarly outputs two signals of positive and negative phases, most of the switching elements SW are set so that two of the elements have states determined by the storage information of a single memory cell in the wiring connection information storage circuit CDM. Only exceptional switching elements are elements SW17 and SW18 which enable connection between a data input line DIN for supply of setting data to the memory cells of the variable logic circuit VLC and the signal lines of the vertical field programmable logic array VLA. Each of these switching elements SW17 and SW18 is associated with a single memory cell in the wiring connection information storage circuit CDM in a 1:1 relationship. In FIG. 9, the switching element having the same reference numeral as that of the memory cell given in the wiring connection information storage circuit CDM is associated with the memory cell.

Shown in FIG. 10 is a more specific example of the circuit configuration of the embodiment of FIG. 9 represented in terms of elements. In the drawing, switching elements are provided at ones of intersection points between vertical and horizontal signal lines denoted by marks “\mathring{x}”. The memory cells M1 to M18 in the wiring connection information storage circuit CDM have the same structure as the memory cells MC1 to MC4 in the logic-setting memory array, except that the number of selecting MOS FET 's Q11, Q21, Q12, and Q22 is smaller by one set than the number of memory cells M1 to M18 in the wiring connection information storage circuit CDM. Select signal lines SL1 to SL9 for the memory cells M1 to M18 in the wiring connection information storage circuit CDM are provided separately from signal lines for the wiring zones VLA and HLA.

The 18 memory cells M1 to M18 in the wiring connection information storage circuit CDM are provided in two columns associated with two columns of the memory cells MC1 to MC4 in the memory array MCA of the variable logic circuit VLC, input and output terminals of the memory cells M1, M3, . . . in the left-side column are connected to the common data lines DL1 and /dl1 respectively, and input and output terminals of the memory cells M2, M4, . . . in the right-side column are connected to common data lines DL2 and /DL2 respectively. In the present embodiment of FIG. 10, in this way, the select signal lines SL1 to SL9 of the memory cells M1 to M18 in the wiring connection information storage circuit CDM are separately provided so that selection of any one of the select signal lines enables data to be set separately through the same data line.

As will be clear from FIG. 10, since the FPLA using the variable logic cell circuit LCL of the present embodiment includes memory cells most of which have a structure similar to known SRAM memory cells, a fine processing technique or know-how of layout design already developed for the SRAM can be applied. Accordingly the FPLA can be provided as a part of the SRAM already provided on a semiconductor chip, or a relatively large number of variable logic cells can be embedded in an idle space between circuit blocks. Although 4 pairs of connection wiring lines in the vertical direction and 3 pairs of connection wiring lines in the horizontal direction have been provided per one variable logic cell in the embodiment of FIGS. 9 and 10, the number of such wiring lines is not limited to the above specific values. When the number of wiring lines and the number of connection switches are increased, connection with other variable logic cells can be more facilitated and thus determination of wiring line connection information for formation of a desired logic can be facilitated.

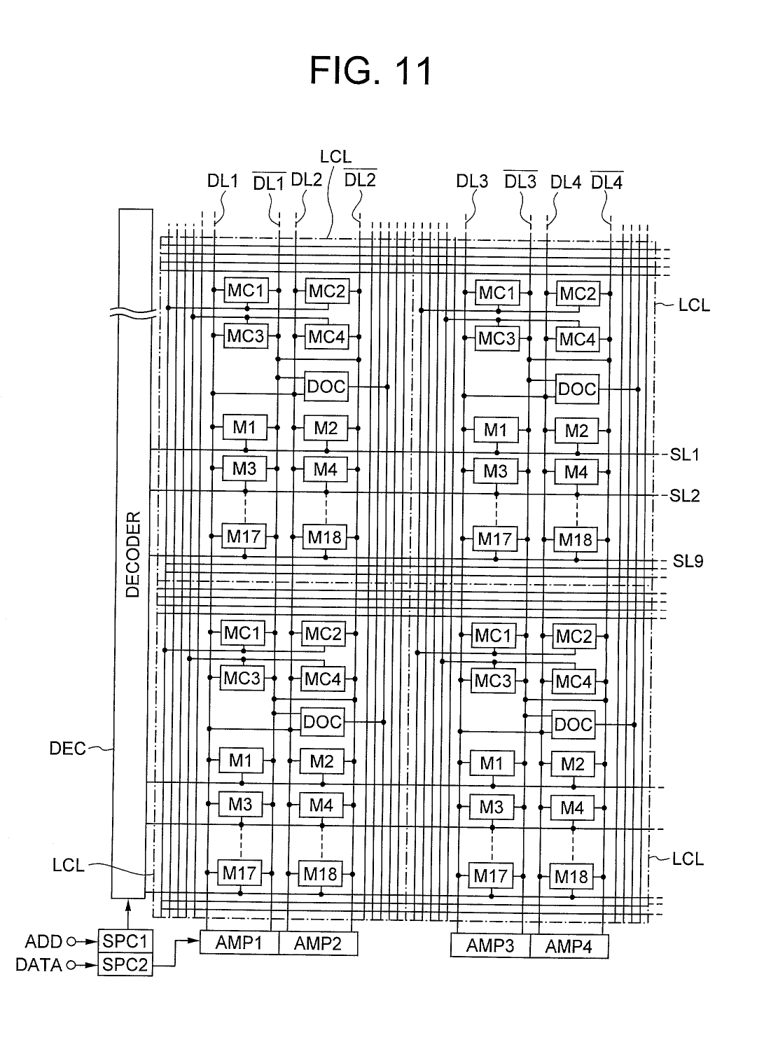

FIG. 11 shows an example of a system of writing wiring-line connection information in the memory cells M1 to M18 in the wiring connection information storage circuit CDM when the variable logic cell circuits LCL of the embodiment are arranged on a semiconductor chip in the form of a matrix to form an FPLA. In the present embodiment of the same drawing, for a plurality of variable logic cell circuits LCL arranged in the horizontal direction, the select signal lines SL1 to SL9 for supply of select signals of the memory cells M1 to M18 in each circuit are provided as lines common to the cells in the horizontal direction, and one ends of the select signal lines SL1 to SL9 are connected to a decoder DEC. In FIG. 11, however, switches at intersection points between signal lines in the vertical and horizontal directions are not illustrated and omitted.

The decoder DEC is arranged to decode an address signal input from the outside of the chip to put any one of the select signal lines SL1 to SL9 to a select level. And ones of the memory cells M1 to M18 in the plurality of variable logic cell circuits LCL connected to the signal line put to the select level are connected at their input and output terminals to the data lines DL1, /DL1; DL2, /DL2; . . . The data lines DL1, /DL1; DL2, /DL2; . . . are connected at their one ends with amplification circuits AMP1, AMP 2, . . . which have substantially the same structure as sense amplifiers used in SRAM or the like, so that, external write data is input to the amplification circuits AMP1, AMP2, . . . , wiring-line connection information is written in the then selected memory cell.

Although not illustrated, the data lines DL1, /DL1; DL2, /DL 2; . . . are extended to the opposite side of the amplification circuits AMP1, AMP 2, . . . , and the input and output terminals of the memory cells M1 to M18 in the plurality of variable logic cell circuits LCL vertically arranged on the chip are commonly connected the extended data lines DL1, /DL1; DL2, /DL2; . . . At the same time, the decoder DEC is arranged as associated even with a plurality of the variable logic cell circuits LCL arranged in the vertical direction, so as to drive one of the select signal lines SL1 to SL9 in any one of the plurality of variable logic cell circuits LCL to the select level.

In the present embodiment, further, for the purpose of reducing the number of external terminals, an address signal ADD to be supplied to the decoder DEC is input serially from one input terminal, also converted by a serial/parallel conversion circuit SPC1 to parallel signals, and then supplied to the decoder DEC. Similarly, wiring-line connection information DATA to be written in the memory cells M1 to M18 within the variable logic cell circuits LCL is also input serially from one input terminal, also converted by a serial/parallel conversion circuit SPC2 to parallel signals and then supplied to the amplification circuits AMP1, AMP2 . . .

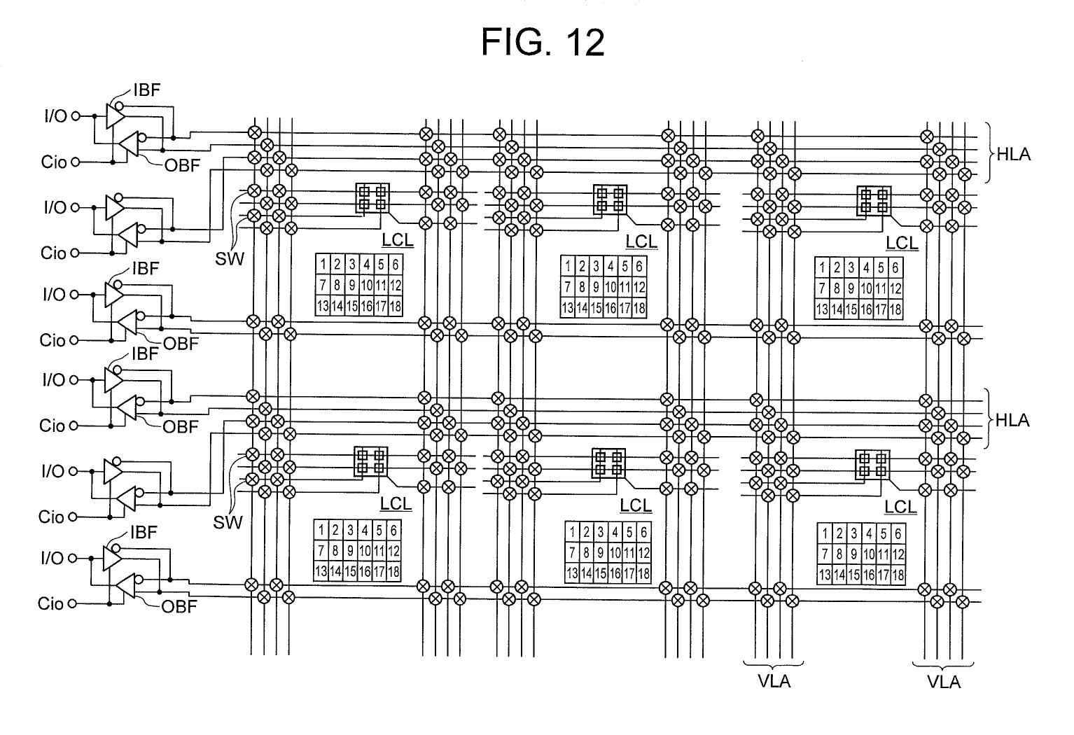

FIG. 12 shows an example of a system of writing logic setting information in the memory cells MC1 to MC4 for logic setting when the variable logic cell circuits LCL of the embodiment are arranged on a semiconductor chip in the form of a matrix to form an FPLA. In the embodiment of the same drawing, input buffers IBF and output buffers OBF are connected to ends of signal lines of the wiring zones HLA arranged in the horizontal direction in the form of a grid one the chip peripheral edge side thereof.

Each of the input buffers IBF receives one input signal from each corresponding external terminal I/O, generates signals of positive and negative phases and supplies them to the internal circuit. Each of the output buffers OBF receives signals of positive and negative phases from the internal circuit, and outputs any one of the signals of the positive and negative phases to each corresponding external terminal I/O as a single signal. Here is the reason why such two signals of positive and negative phases are transmitted in the chip. An attempt to reduce the power voltage of an LSI has been studied in these years. Thus even when the power voltage of the chip became as low as 3.0V or 1.8V, the present invention can transmit a right signal while not affected by noise and eliminating the need for circuit modification. In addition, the signals to be supplied to the variable logic cell circuits LCL have positive and negative phases. Thus in the variable logic cell circuit of the embodiment including the four logic setting memory cells, when the input signal is given as it is as a select signal of the memory cells MC1 to MC4 for logic setting, an output signal similar to when the input signal is passed through an ordinary two-input logic gate can be immediately obtained.

In the present embodiment, the input buffers IBF and output buffers OBF connected to the same signal line are connected to the common external terminal I/O, so that a control signal Cio causes only any one of the input and output buffers IBF and OBF to be activated, thus reducing the number of necessary terminals, although not specifically limited to the example. The control signal Cio may be externally provided for each external terminal I/O or may be provided for each of several groups of the external terminals I/O as a common signal. Further, the control signal Cio is also arranged desirably to be able to be supplied from the chip internal circuit through the signal lines of the wiring zones VLA and HLA. Although not illustrated, the input and output buffers IBF and OBF may similarly be connected even to ends of the signal lines provided to the wiring zone VLA in the vertical direction and on the chip peripheral edge side.

In the FPLA arranged as mentioned above, when predetermined data is written in the memory cells MC1 to MC4 for logic setting in the variable logic cell circuits LCL provided on the chip and when predetermined wiring-line connection information is written in the memory cells M1 to M18 for storage of the wiring-line connection information, the states of the switching elements SW at the intersection points between the signal lines provided to the wiring zone VLA can be suitably set and thus a desired logic can be formed with use of any of the variable logic cell circuits LCL on the chip.

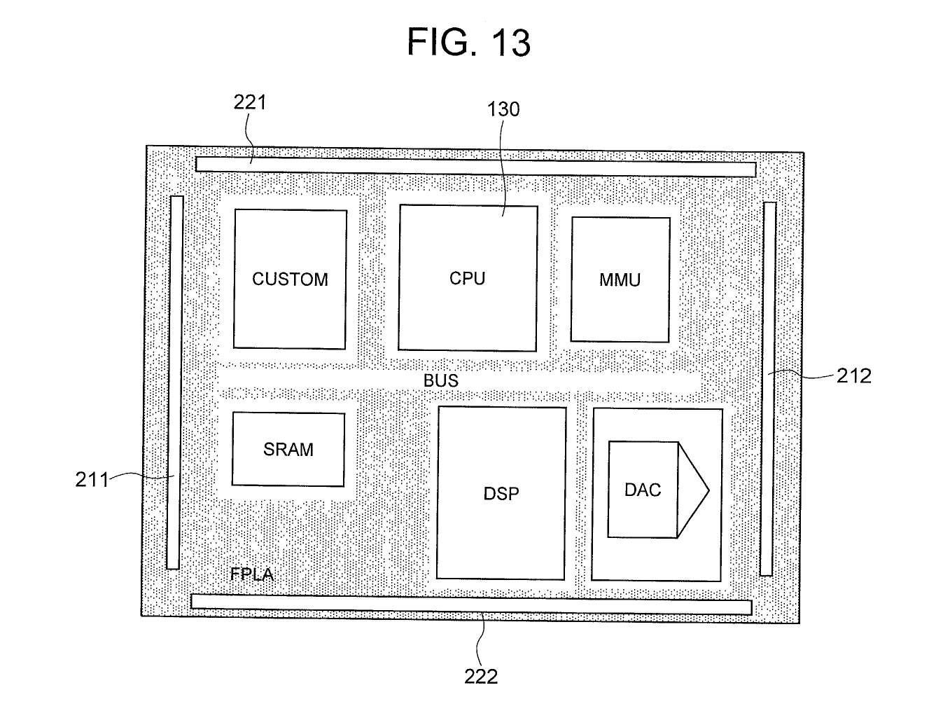

FIG. 13 is a block diagram of a system LSI in accordance with another embodiment of the present invention. In the drawing, reference symbol CPU denotes a central processing unit, symbol ROM denotes a read only memory for storing a program or the like therein, SRAM denotes a static memory for providing a work area to the CPU, MMU denotes a memory management unit for performing cache control, memory allocation, etc., DSP denotes a digital signal processor for performing operations for signal processing in place of the CPU, CUSTOM denotes a custom logic circuit (user logic) having a function desired by the user, and DAC denotes an analog circuit DAC for performing D/A conversion.

In the system LSI of the present embodiment, the variable logic cell circuits LCL having such an arrangement as shown in FIG. 10 and variable analog cells (to be explained later) are arranged so as to fill idle gaps between the circuit blocks, decoder circuits 211 and 212 for data input to the variable logic cell circuits LCL and variable analog cells as well as sense amplifiers 221 and 222 are previously provided in the peripheral edge of the chip, so that the variable logic cell circuits LCL and variable analog cells are used to form a logic test circuit for the CPU or RAM and to form an analog test circuit for the D/A conversion circuit DAC or the like, thus enabling realization of its self test.

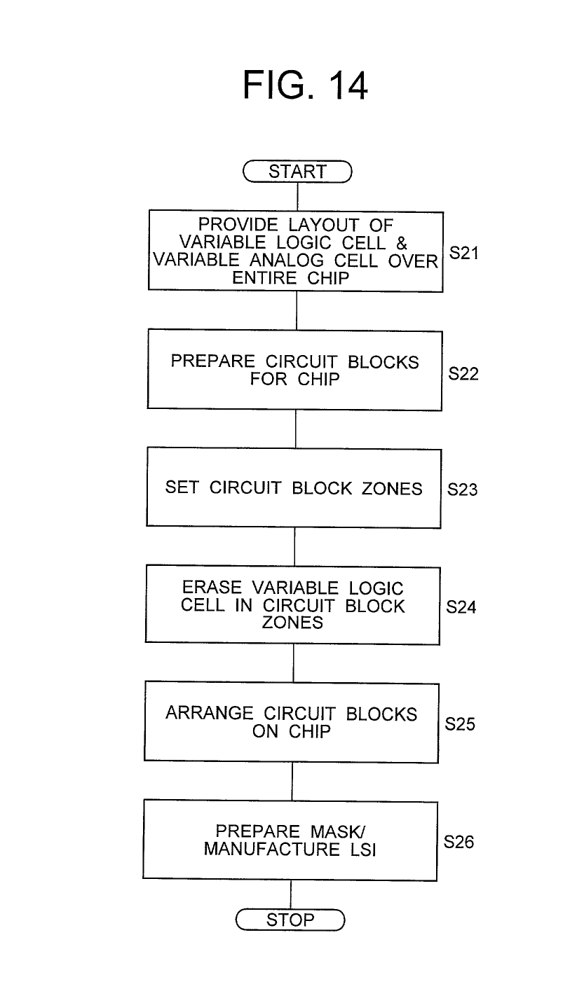

FIG. 14 shows a procedure of how to design, inspect and manufacture such a system LSI as mentioned above.

Upon designing the system LSI of the present embodiment, the system first arranges the variable logic cell circuits LCL and variable analog cells in the foregoing embodiment as filled on a semiconductor chip without any gap with use of a design support tool such as a DA program, and arranges the decoder circuits 211 and 212 (corresponding to the decoder DEC in FIG. 11) for selection of one of the variable logic cells and variable analog cells as well as the sense amplifier rows 221 and 222 (corresponding to the amplification circuits AMP in FIG. 11) for read/write of the selected memory cell along the sides of the chip 100 to thereby form an entire FPLA (step S21).

Next the system prepares circuit blocks of the system LSI such as the central processing unit CPU, read only memory ROM, static memory SRAM, dynamic memory DRAM, memory management unit MMU, digital signal processor DSP, and custom logic circuit (user logic) CUSTOM (step S22). And considering the shapes and sizes of these circuit blocks, the layout of a bus BUS for connection between the circuit blocks, etc., the system determines a layout on the semiconductor chip as shown in FIG. 13 (step S23).

Subsequently, the system erases ones of the variable logic cells and variable analog cells arranged as the entire FPLA in the step S21 and included in zones overlapped with the layout positions of the circuit blocks determined in the step S23 (step S24). Then the system arranges the circuit blocks in the above cell-erased zones and designs signal lines and power lines for connection between the circuit blocks (step S25).

At this time, if the FPLA is cut at the interface between variable logic and analog cells, then it can be used as its entirety. However, if the FPLA is cut at some midpoint of the variable logic or analog cells and there is an element which cannot function effectively, then the system desirably performs such termination processing operation as to cut off connections of the power or grounding line connected to such an element. Further, when a cell is partly overlapped with a circuit block and thus the cell is partly missing, it is also possible to erase the entire cell partly missing.

Thereafter, the system prepares a mask based on design data and forms a system LSI on a wafer by a manufacturing process with use of the prepared mask (step S26). After the system LSI is manufactured in such a manner as mentioned above, a test is carried out in accordance with a procedure similar to the flowchart of FIG. 6 to see if each of the circuit blocks is operating normally. In this connection, the test is carried out the probe inspection of the wafer state.

In the wafer test, first, a test apparatus or logic synthesis/write apparatus for testing an FPLA part remaining in the gap between the circuit blocks or in the vicinity thereof is used as an external apparatus. Usable as the test or logic synthesis/write apparatus is an ordinary personal computer or the like.

After the above preparation was done, the system starts a program for the test apparatus. Then the test apparatus inputs an address signal for assignment of the variable logic cell to the decoders 211 and 212 to put the variable logic cell in its selected state, and writes connection information of the selected variable logic cell in the memory cell of the wiring connection information storage circuit CDM to cause the variable logic circuit of one variable logic cell in the FPLA to be put in such a state as to be connected with an external terminal.

Next the test apparatus sends test data of 4 bits to the memory cells MC1 to MC4 for logic setting within the selected variable logic cell, writes it and reads out it to compare it with an expected value, repeats its operation with changed patterns of the test data to judge whether or not the variable logic cell is normal. When the cell is not normal, the test apparatus specifies the defective cell on the basis of the test result and stores the defective logic cell in the test apparatus. At this time, the test apparatus can know the non-existence of variable logic cells due to the aforementioned zone erasure and stores such cells therein. Similarly the test apparatus tests even variable analog cells to detect defective or non-existence cells. The above variable logic cell test involves only a large number of such cells to be tested but the test pattern for each cell can be made small in scale. As a result, the burden imposed on the test apparatus can be made very light and an inexpensive tester can be instead used.

The defective logical cells thus detected include not only defective ones of the logic-setting memory cells MC1 to MC4 for writing of the test data therein but also defective ones of the switching elements SW at intersection points between signal lines for transmission of a signal to the logic unit to be inspected and defective ones of the memory cells of the wiring connection information storage circuit CDM for storage of ON/OFF states of switching elements. Even in the case where the memory cells MC1 to MC4 for logic setting are normal, if one switching element is destroyed or one memory cell of the wiring connection information storage circuit CDM is defective, then the test apparatus cannot read the written data, as a result of which the apparatus can grasp the presence of the defect. When the test pattern is devised, the test apparatus may detect a defective element or signal path in the defective logic cell and store the defective element or path therein. Even with respect to the variable analog cells, the test apparatus can similarly detect defective one thereof.

After completing the detection and storage of the defective cells, the test apparatus lists normal variable logic cells and variable analog cells and selects ones of the listed variable logic and analog cells which are to be used to form a test circuit. Then the test apparatus forms a test circuit for test of the circuit blocks in a set zone. More specifically, the test apparatus writes predetermined data in the logic-setting memory arrays in the variable logic cell in the embodiment to form logic gates necessary for forming a test circuit, generates inter-line connection information for connection between logic gate circuits thus arranged and having a predetermined logic function, writes the information in the wiring connection information storage circuit CDM in the logic unit to thereby form a test circuit. At this time, the test apparatus may describe the test circuit in a hardware description language (HDL) by an HDL technique, automatically generate data to be stored in the memory in the variable logic cell on the basis of the described HDL under control of a computer, write the generated data in the normal variable logic cell to form a test circuit.

The test circuit formed in the FPLA includes a controller based on a microinstruction, a data calculator and a means for judging read-out data and outputting a judgement result. A test technique called an algorithmic memory pattern generator (ALPG) for generating a test pattern in accordance with a predetermined algorithm and reading out written data can be applied to such a test circuit.

After the test apparatus forms the test circuit for circuit blocks of the chip in the already-inspected FPLA, the apparatus inspects the respective circuit blocks with use of the test circuit. Although the test circuit can be formed as a test circuit common to plural ones of the circuit blocks, one test circuit of the optimum algorithm may be re-formed for each of the circuit blocks for the test. A test signal from the test circuit to each circuit block may be supplied through extensions of signal lines of the wiring zones VLA1, VLA2, HLA1 and HLA2 forming the variable logic cell in FIG. 9, or may be supplied through the system bus connected to the wiring lines of the wiring zones VLA1, VLA2, HLA1 and HLA2.

Further, after completing the above test, the test apparatus may leave the test circuit as it is or may erase the logic memories forming the test circuit from the memory elements in each variable logic cell. Or the test apparatus may reform the FPLA having the test circuit formed therein into an SRAM in such a manner that a circuit block (e.g., CPU) on the chip can be used as a work or storage area, or may use it as a logical circuit forming a part of the user logic.

When finding a defect in a part of any of the circuit blocks through the above test, the test apparatus may form a repair circuit for correcting the defect circuit in the FPLA. In this case, the test apparatus may rewrite its stored logic and connection information with use of the variable logic cell and variable analog cell so far forming the test circuit to form a repair circuit, or may repair the defective block with use of the variable logic cell and variable analog cell not used in the formation of the test circuit.

Further, when it is desired to develop a new product having an improved user logic circuit, the test apparatus can form a new user logic circuit by utilizing the FPLA, and perform emulation for evaluation. Even when it becomes necessary to modify the user logic circuit after completion of an LSI or when to partly add a new function, such modification or function addition can be easily realized by utilizing the FPLA. And even in this case, similarly to the test circuit, the test apparatus can describe the user logic in the HDL and automatically form a desired logic on the FPLA on the basis of the described HDL under control of a computer.

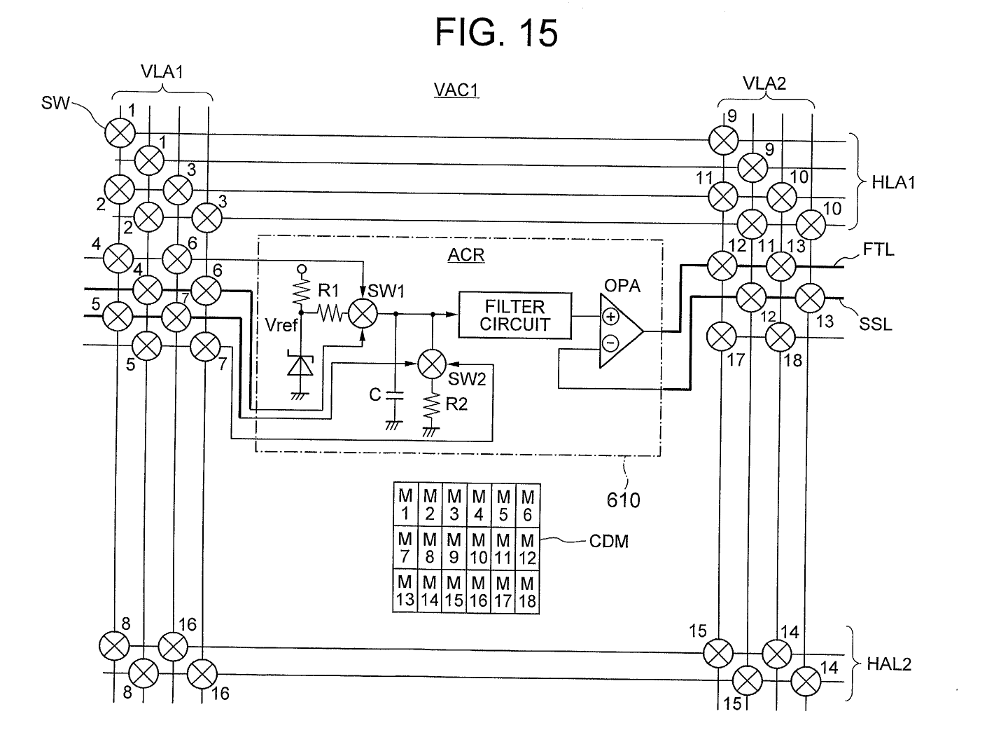

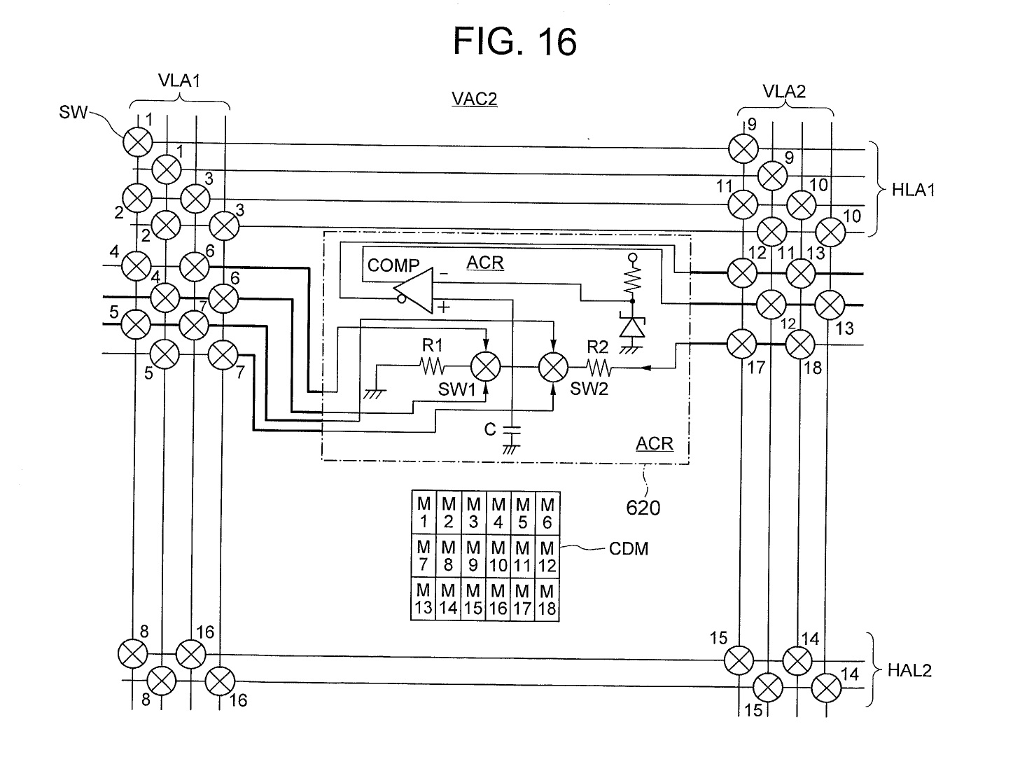

An example of a variable analog cell forming an FPLA will be explained with reference to FIGS. 15 to 18. As will be seen from FIGS. 15 and 16, there are two types of variable analog cells. FIG. 15 is one type of cell having an arrangement similar to the voltage generation circuit 610 shown in FIG. 2, whereas, FIG. 16 is the other type of cell having an arrangement similar to the voltage measurement circuit 620 shown in FIG. 5. Variable switch circuits and wiring lines for enabling connection between such a cell and any one of circuits on the chip are provided around the voltage generation circuit 610 or voltage measurement circuit 620 (which will be referred to as the analog core ACR, hereinafter).

The analog core ACR of FIG. 16 has exactly the same arrangement as the voltage measurement circuit 620 of FIG. 5. However, the analog core ACR of FIG. 15 is slightly different from the voltage generation circuit 610 of FIG. 2 in that the analog core of FIG. 15 has an output amplifier OPA which includes the differential amplification circuit 615 and final output stage 616 shown in FIG. 3 at the last stage. This is for the purpose of outputting a voltage issued from the variable analog cell in the two-line manner of the force and sense lines.

Each of the variable analog cells VAC1 and VAC2 of FIGS. 15 and 16 has an arrangement similar to the variable logic cell shown in FIG. 9. More concretely, in the variable analog cells of FIGS. 15 and 16, the variable logic circuit VLC in the variable logic cell of FIG. 9 is replaced by the voltage generation circuit 610 or voltage measurement circuit 620 respectively. That is, the variable analog cells of FIGS. 15 and 16 respectively include a grid-shaped wiring zones VLA and HLA, switching elements SW provided at intersection points between the wiring lines provided to the wiring zones VLA and HLA, a voltage generation circuit 610 or voltage measurement circuit 620 provided in the rectangular zone surrounded by the wiring zones VLA and HLA, and a wiring connection information storage circuit CDM.

In the variable analog cells of the embodiments of FIGS. 15 and 16, the wiring zones VLA and HLA provided around the voltage generation circuit 610 or voltage measurement circuit 620, switching elements SW and wiring connection information storage circuit CDM have exactly the same structures as those of the variable logic cell of FIG. 9. Even in such a case, the voltage generation circuit 610 or voltage measurement circuit 620 (which will be referred to as the analog core ACR, hereinafter) can be connected with any one of the circuits on the chip, and the formation of the above same structures enables facilitated design and efficient layout resulting from the regularly arranged cells.

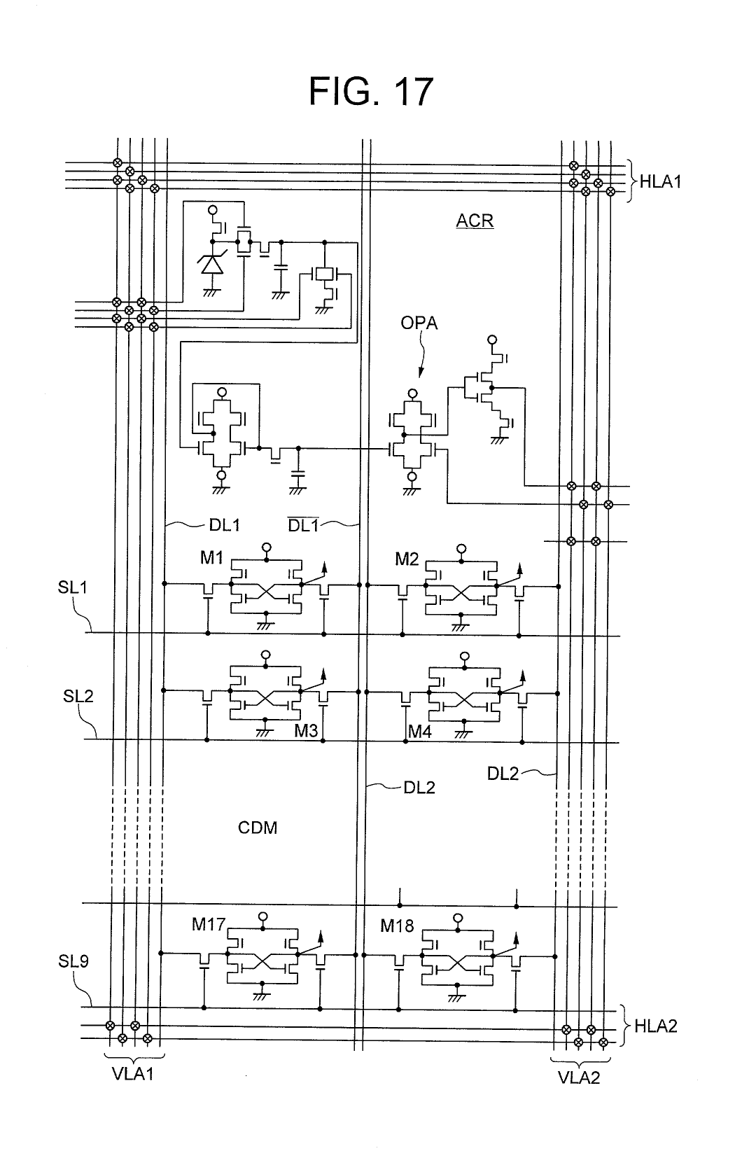

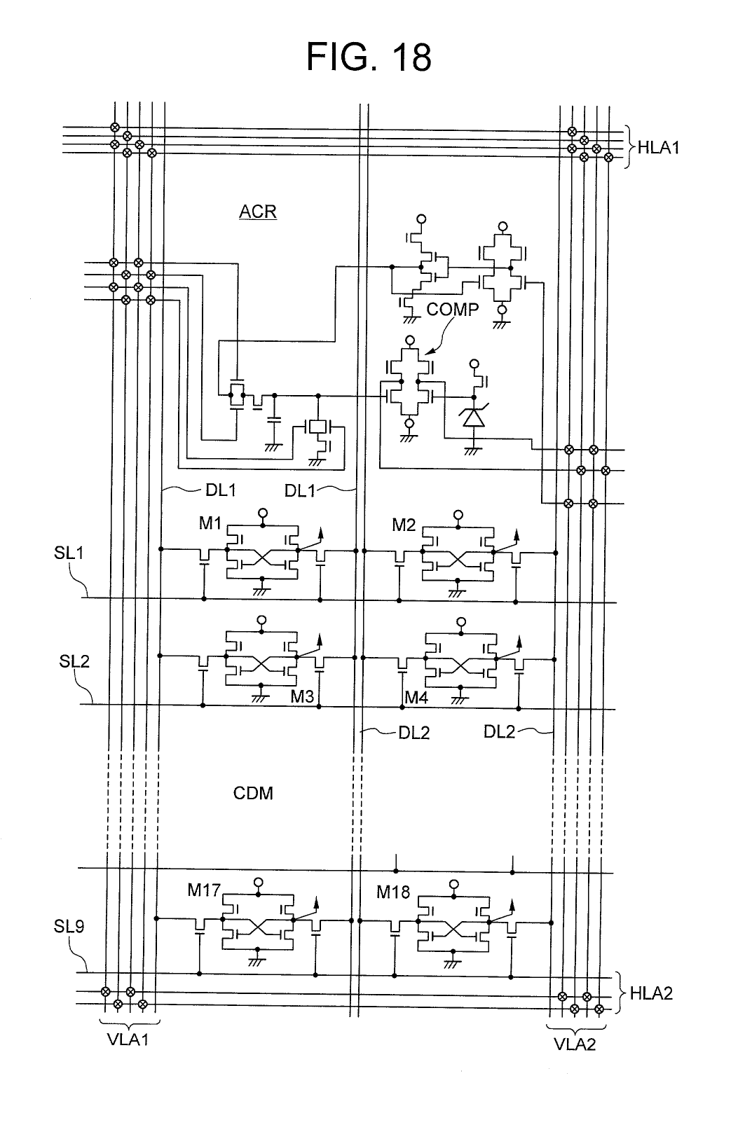

FIG. 17 is a more detailed example of the circuit configuration of the variable logic cell of FIG. 15, and FIG. 18 is a more detailed example of the circuit configuration of the variable logic cell of FIG. 16.

As will become clear from comparison between FIGS. 17 and 18 and FIG. 10 of the detailed example of the variable logic cell, the analog core ACR of the variable analog cell has a structure similar in circuit to the variable logic circuit VLC of the variable logic cell. That is, in the present embodiment, the analog core ACR of the variable analog cell and the variable logic circuit VLC of the variable logic cell are based on an assembly of exactly the same elements. In other words, elements necessary to form the variable analog cell and variable logic cell are previously formed with used of the same mask, and the analog core ACR and variable logic circuit VCL can be formed by changing only the wiring pattern.

This enables easy design and effective cell layout based on the regularly-arranged cells. The number of elements forming the variable logic circuit VCL of FIG. 10 is 40, the number of elements forming the analog core ACR of the variable analog cell of FIG. 17 is 25, and the number of elements forming the analog core ACR of the variable analog cell of FIG. 18 is 23. Further, a resistive element is replaced by the resistance of a channel of the MOS FET, a capacitive element is replaced by the capacitance between the gate electrode of the MOS FET and the source and drain thereof, and a diode is also replaced by the MOS FET having the gate and drain coupled to each other. Accordingly, when elements necessary and sufficient to form the variable logic circuit VCL of the variable logic cell are previously formed, the analog core ACR of FIG. 17 or 18 can be formed using the previously-formed elements.

In the present embodiment, further, a pair of connection wiring lines used for transmission of the differential signals between the variable logic cells are used as the force and sense lines of the two-line transmission system for the analog signals in the variable analog cell. In FIGS. 15 and 16, reference numeral FTL denotes the force line and SSL denotes the signal line for feedback. In FIG. 16, a switch SW17 implements a so-called a Kelvin contact for connecting the force and sense lines at termination ends of transmission lines of the analog signals.

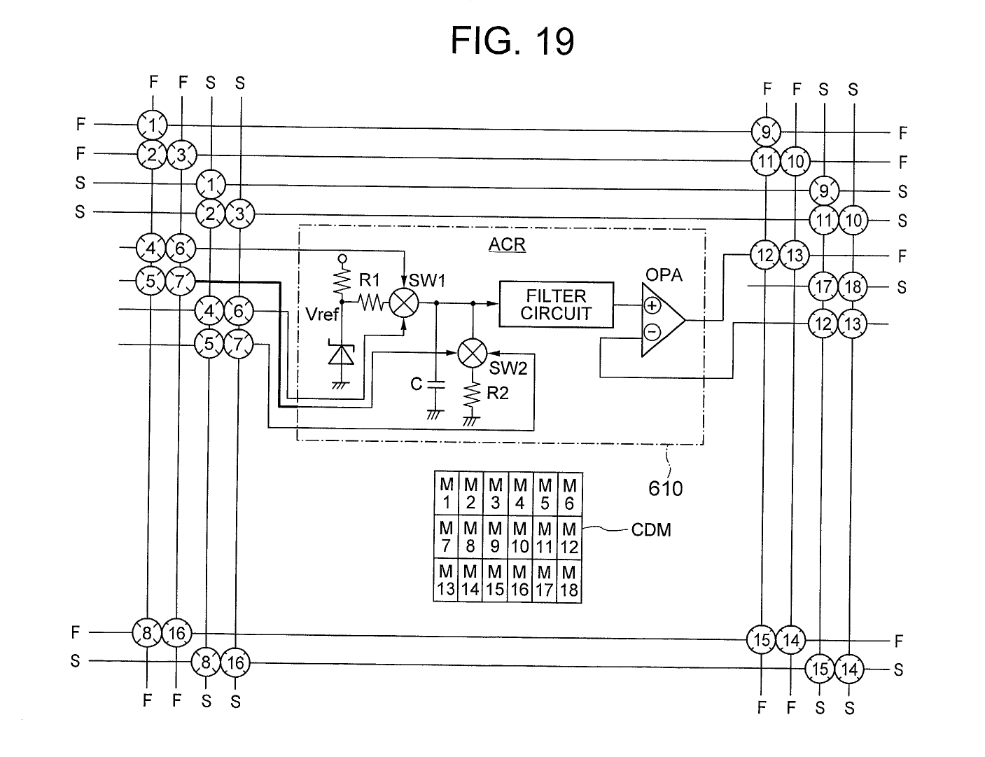

When the two-line system of the force and sense lines are employed for the transmission of the analog signals as mentioned above, it is desirable to use a relatively thick wiring line as the force line and a relatively thin wiring line as the sense line, as shown in FIG. 19. In FIG. 19, reference numeral denotes the force line and symbol S denotes the signal line respectively.

As mentioned above, since the current flowing through the force line is larger than the current flowing through the sense line, the above different thicknesses of the force and sense lines are for the purpose of reducing the voltage drops generated thereby. Further, it is desirable to provide the force and force lines in parallel and also to provide the sense and sense lines in parallel. With such an arrangement, when a defect of a short-circuiting between adjacent lines takes place, it can be avoided that the short-circuited location acts as a Kelvin contact and an erroneous voltage is fed back.

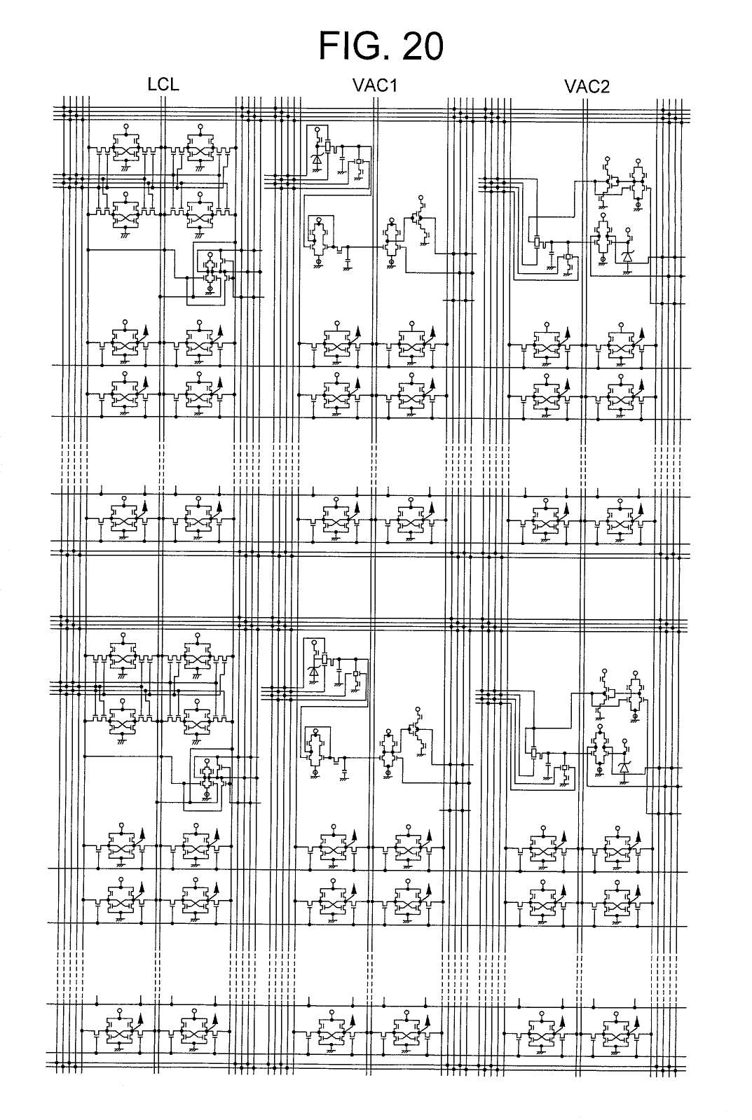

In an LSI of an analog/digital mixture type wherein an analog circuit such as the D/A conversion circuit DAC and a digital circuit such as the custom logic circuit CUSTOM are formed on a single chip like the system LSI of FIG. 13; when it is desired to test an analog or digital circuit with use of a test circuit made up of variable logic cells or variable analog cells arranged as filled in the idle spaces between the circuit blocks, the variable logic cell circuits LCL of the structure of FIG. 10 and the variable analog cells VAC1 and VAC2 of the structures of FIGS. 17 and 18 are arranged desirably alternately as filled as shown in FIG. 20.

With such an arrangement, when test is carried out with use of a test circuit of the variable logic cell for the digital circuit and then when test is carried out with use of a test circuit of the variable analog cell for the analog circuit, both the analog and digital circuits can be tested with use of the on-chip test circuits. Further, when the test circuit for the analog circuit is made up of the variable analog cell, a circuit is required for generating a control pulse to operate such an analog circuit as shown in FIG. 2 or 5. However, such a pulse generating circuit can be formed with the variable logic cell used when the test circuit for the digital circuit is formed.

In general, the number of variable logic cells required to form a test circuit for a digital circuit is considered to be larger than the number of variable analog cells required to form a test circuit for an analog circuit. In place of arranging the variable logic cell of the structure of FIG. 10 and the variable analog cell of the structure of FIG. 17 or 18 in a ratio of 1:1:1 as shown in FIG. 20; it is desirable to arrange the variable logic and analog cells in an arbitrary ratio of, e.g., n:1:1 (n being a positive integer) according to a desired test circuit to thereby form the FPLA in the idle spaces between the circuit blocks. Even in the case where the cell ratio is changed, when the variable logic and analog cells are formed to have a similar structure as in the foregoing embodiment, its design modification can be advantageously realized highly easily only by replacing the cells.

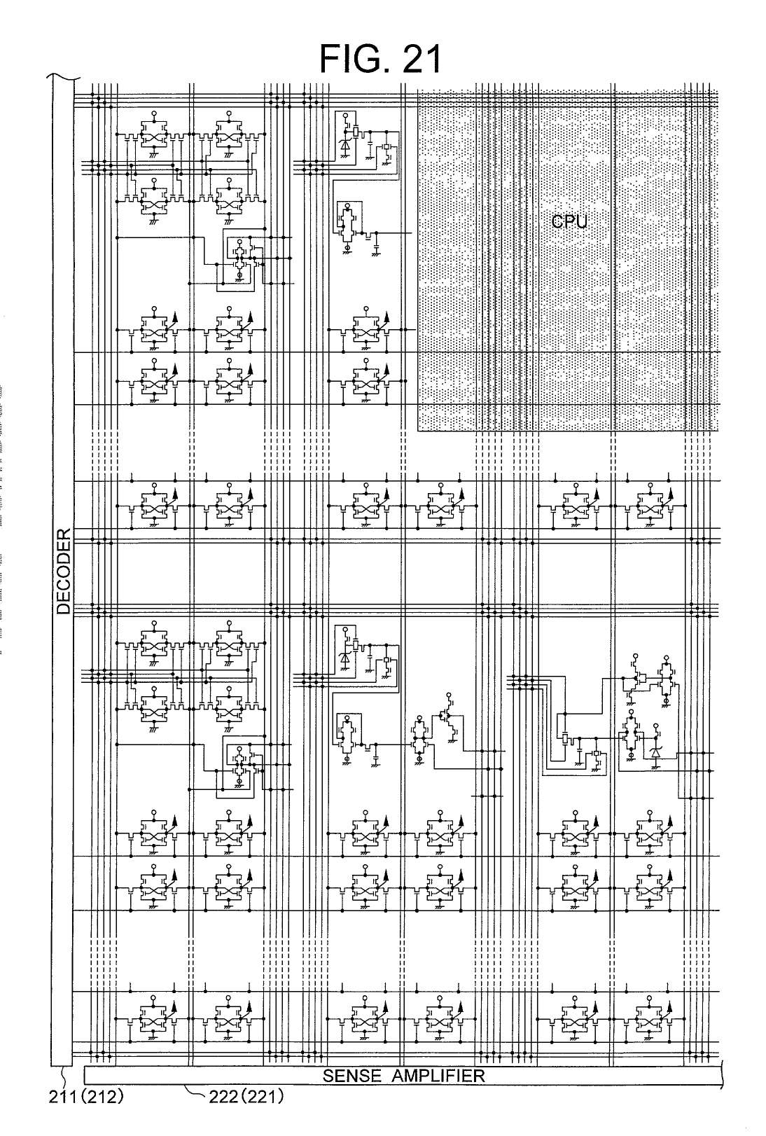

FIG. 21 shows a detailed example of wiring lines provided in the FPLA. As mentioned above, the variable logic or analog cell in the FPLA has a variable wiring means for enabling connection between any ones of the signal lines. With regard to the variable logic circuit VLC or analog core ACR, an external signal can be input to the variable logic cell at any location on the chip and be output therefrom. With regard to the select signal lines (SL1 to SL9 in FIGS. 10, 17 and 18 ) of the memory cells in the wiring connection information storage circuit CDM or the data input/output lines (DL1, /DL1; DL2, /DL2, etc.), however, when a circuit block is arranged on the chip, a wiring line may be broken and thus there may occur a variable logic or analog cell at which the signal cannot arrived.

Further, in the case where circuit blocks are arranged on the semiconductor chip as shown in FIG. 13, when a test circuit in the form of an in-chip circuit block is formed by utilizing a relatively broad excess zone having in the upper right corner, a test signal can be easily supplied to adjacent one of the circuit blocks such as MMU or ADC but it becomes difficult to supply the test signal to one of the blocks such as SRAM at a position away from the test circuit. Similarly, even when variable logic cells in an excessive part after the test is completed are used to form a part of the user logic, the signal transmission between the formed circuit and another circuit block is considered difficult.

To avoid this, in the present embodiment, signal lines arranged across a plurality of variable logic or analog cells are formed in the form of a wiring layer added separately from the signal lines of the circuit blocks. More specifically, when the signal and power wiring lines of the circuit blocks such as CPU and DSP in FIG. 13 are provided in the form of a metallic film of 6 layers, the signal lines arranged across a plurality of variable logic cell circuits LCL are provided in the form of seventh and eighth metallic layers. As a result, as shown in FIG. 21, wiring lines passed over the circuit block such as CPU can be formed to connect the variable logic or analog cells located at both sides of the circuit block and to easily form a desired test circuit.

With respect to power lines provided to the variable or analog cells, even when the variable logic cells located away from each other are separated by a circuit block or even when the variable logic cell is connected to the circuit block, this causes no problem with the power line. Thus the power line of the variable logic or analog cell can be provided in the form of the same metallic layer as the power line of the circuit block. Even with regard to the signal lines (CDL, /CDL, etc. in FIG. 10) within the variable logic or analog cell, the signal lines will not be connected directly to an element outside of the cell. Thus the above signal lines can be provided in the form of the same metallic layer (usually, the first layer) as the wiring lines for connection between elements such as logic gates or flip-flops in a circuit block.

As a result, even the variable logic or analog cells present between the circuit blocks can be transmitted with the signal and be effectively utilized as cells of a test circuit or user logic. Further, the test signal can be easily supplied to the circuit block located away from the test circuit and the building of the test function in the chip and speed-up thereof can be realized.

Since a bypass circuit can be easily formed by utilizing the variable wiring means for the variable logic cell, when signal lines provided across a plurality of variable logic or analog cells are made of, e.g., an insulating polyimide film (PIQ) in an inexpensive process with a relatively low reliability, an increase in cost involved by the addition of the wiring layer can be suppressed. In this connection, the formation of a bypass circuit can be realized by utilizing wiring lines for connection between the variable logic cells, a switch of the variable logic cell under a corner of the bypass circuit and a memory cell for storage of the wiring-line connection information.

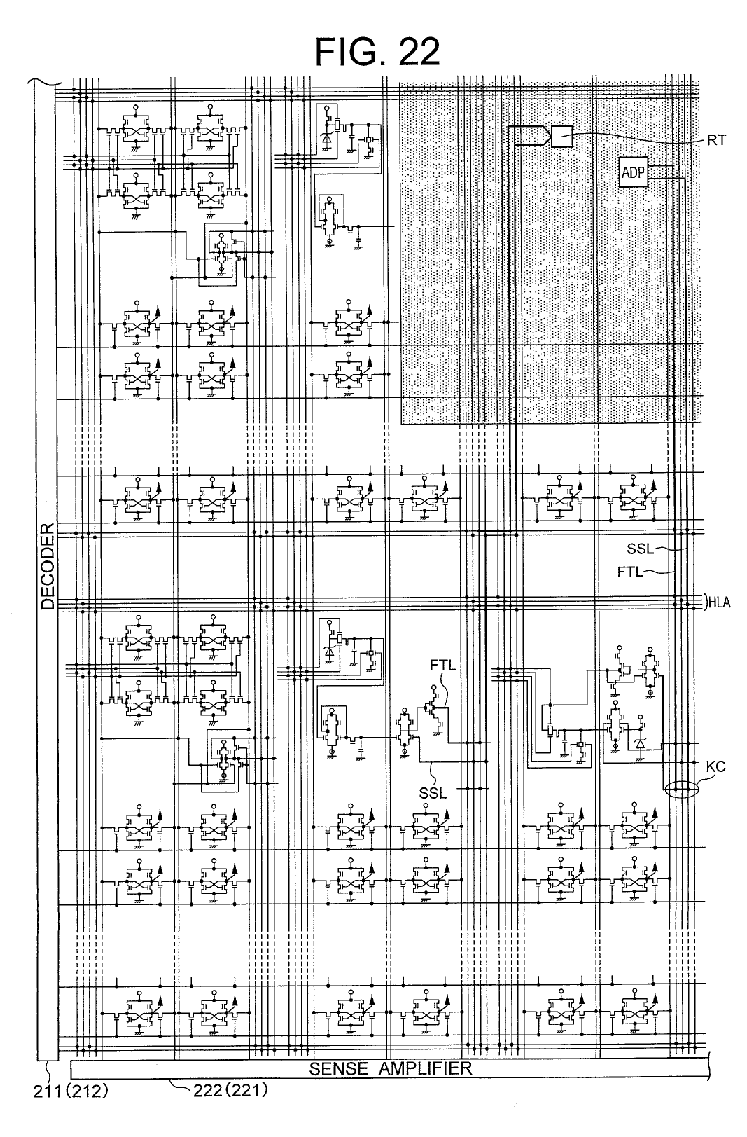

FIG. 22 shows a state when an FPLA provided between an idle space between circuit blocks is utilized to connect the variable analog cells of the FIGS. 15 and 16 and any one of circuits or elements in the circuit block and to form transmission lines for transmission and reception of analog signals. In FIG. 22, reference symbol RT denotes the transistor provided in the signal receiver side to receive a voltage (analog signal) from the voltage generation circuit 610 in FIG. 3. Further, symbol AOP denotes an analog circuit which outputs an analog signal.

The output of the analog circuit AOP is issued to another circuit in the associated circuit block or to another circuit block. In the present embodiment, however, the output voltage of the analog circuit AOP is drawn to the variable analog cell of the FPLA through the test wiring layer, thus enabling measurement of the output voltage of the analog circuit AOP. In the present embodiment, further, since the inter-cell connection wiring lines (VLA and HLA) forming the FPLA form a pair of wiring lines, the force line FTL and sense line SSL as transmission lines for transmission and reception of the analog signals can be easily provided in parallel to each other as shown in FIG. 22.

Thereby a ratio between a voltage drop across the force line FTL and a voltage drop across the sense line SSL becomes constant regardless of the line routing manner, i.e., the wiring length, thus facilitating circuit design. With the arrangement of the above embodiment, as will be clear from FIG. 22, even when the inter-cell connection wiring lines (VLA and HLA) forming the FPLA are partly disconnected or broken, a transmission line for connection with a desired circuit can be easily set by bypassing the broken location. And even when such a bypassing circuit is set, the signal is transmitted in the two-line system of the force and sense lines to output a high voltage taking the voltage drop into consideration the signal transmitter side, whereby a correct level of signal can be transmitted.

In FIG. 22, for the purpose of arranging to output voltages from the analog circuit AOP (whose output voltage being to be measured) to the variable analog cell in the force/sense manner and to receive at the analog circuit AOP a feedback voltage from the sense line, it becomes necessary for such a differential amplification circuit 615 as shown in FIG. 3 to be provided at an output stage of the analog circuit AOP. However, generally speaking, an analog circuit often has an output amplifier as a differential amplification circuit in its output side. By utilizing it, the transmission of the analog signal in the force/sense manner as shown in FIG. 22 can be realized.

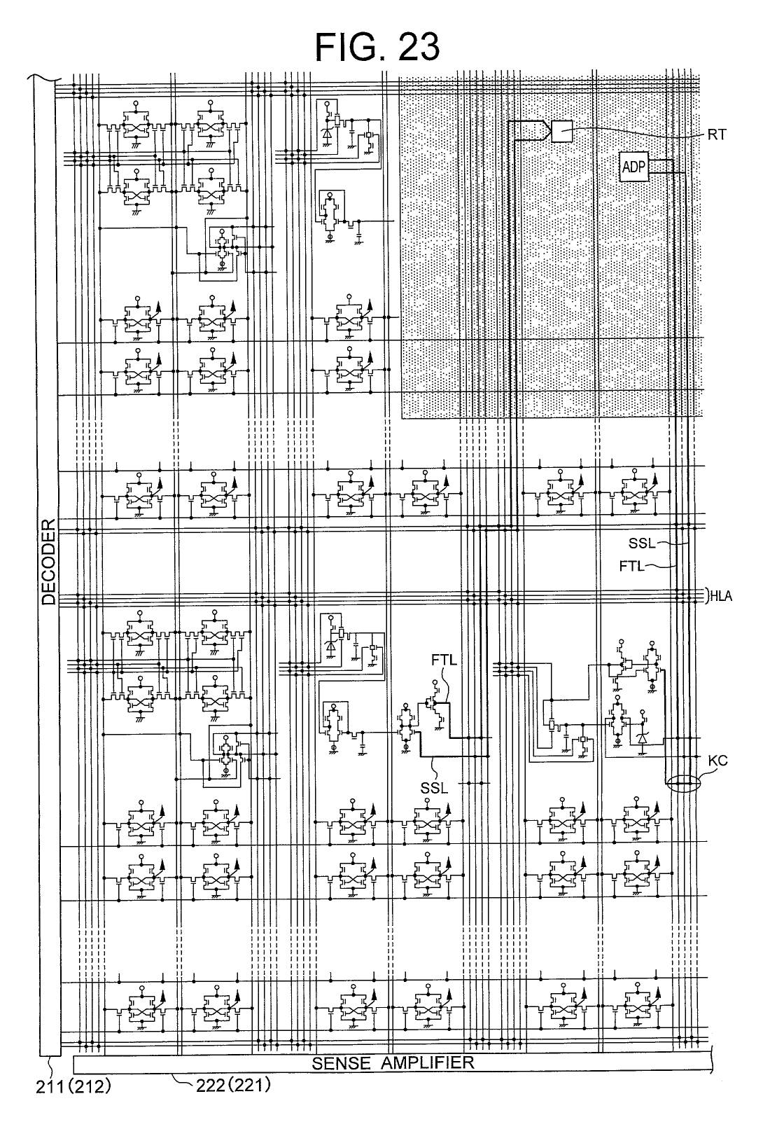

FIG. 23 shows another embodiment of the present invention. The present embodiment is arranged so that, when a defect was detected, e.g., the D/A conversion circuit DAC in circuit blocks of an LSI, the function of the D/A conversion circuit DAC is formed with use of variable analog and logic cells of an FPLA arranged as filled a gap between the circuit blocks, thus improving a chip yield. In FIG. 23, the variable analog and logic cells arranged as filled in an upper right corner of the chip are used to form a substitute D/A conversion circuit DAC′.

In the present embodiment, as shown in the drawing, a wiring line 231 via which an input signal of the original D/A conversion circuit DAC is input to the substitute D/A conversion circuit DAC′ is provided. Also an output signal line 230 for connection between the D/A conversion circuit DAC and an output circuit 241 is broken at a location shown by a mark ‘x’, and instead a wiring line 232 for connection between the D/A conversion circuit DAC′ and output circuit 241 is provided. In this connection, the wiring line 231 is formed desirably by utilizing the aforementioned uppermost layer PIQ.

In the present embodiment, further, the SRAM 140 is formed with use of an ordinary SRAM circuit. The SRAM 150, on the other hand, is formed with use of the variable logic cell of such a structure as shown in FIG. 10. After the variable logic cell is used to form a test circuit for testing another circuit block, the variable logic cell is connected to the system bus BUS so as to be operated as an SRAM accessible from the CPU and to be modified in its wiring connection.

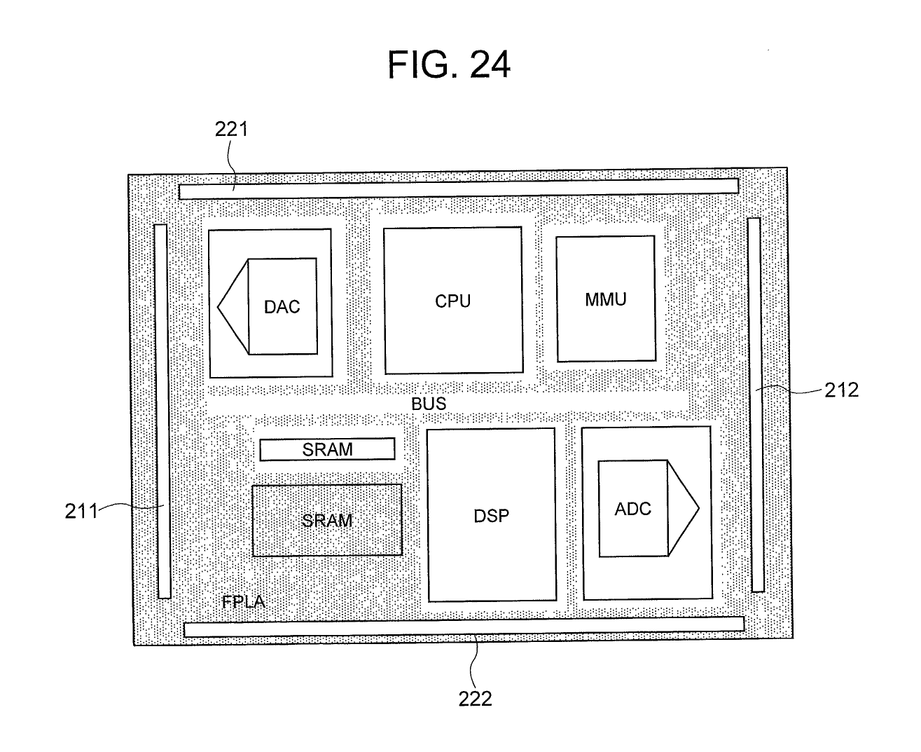

FIG. 24 shows another embodiment of the system LSI having an analog circuit mounted thereon. In the present embodiment, an A/D conversion circuit ADC and D/A conversion circuit DAC, which form a circuit for processing a read signal from and generating a write signal to a medium in a partial response maximum likelihood (PRML) system in a magnetic storage such as a hard disk drive, are mounted on a single semiconductor chip 100 together with a CPU, ARAM and MMU. At the same time, an FPLA having the variable analog and logic cells of the foregoing embodiment is provided in an idle space between circuit blocks so the above variable analog and logic cells are arranged as filled in the space.

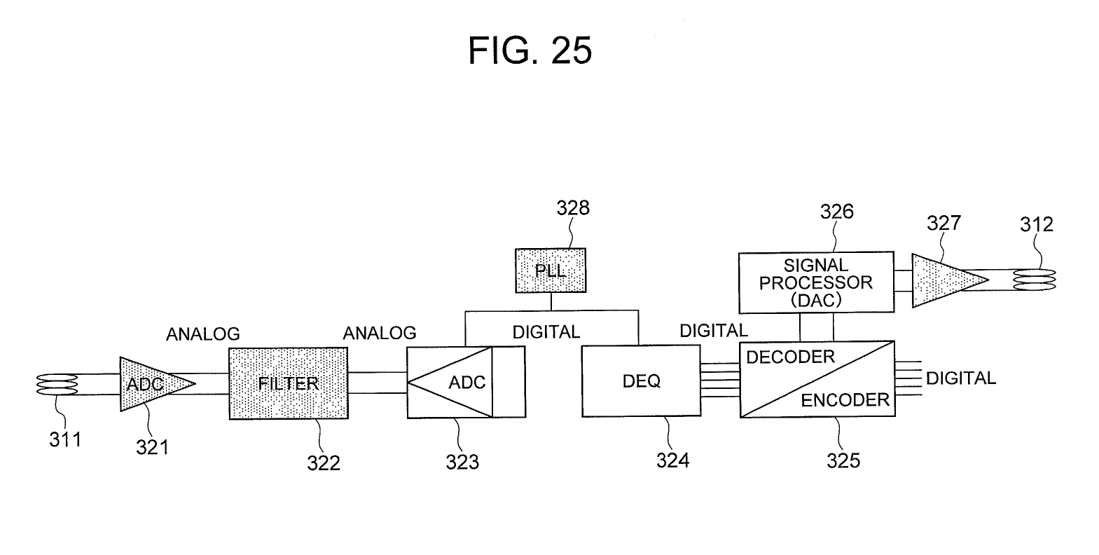

The circuit of the PRML system includes, as shown in FIG. 25, an automatic gain control type amplifier 321 for amplifying a read signal from a reading magnetic head 311, a filter circuit 322 for removing noise frequency components from the amplified signal, an A/D conversion circuit 323 (ADC) for converting the read signal to a digital signal, an encryption circuit 324 (DEQ) for decoding read data encrypted and stored read data or encrypting write signal, an encoder/decoder 325 for encoding the write data or decoding the read data, a signal processing circuit 326 for performing signal processing operation such as conversion of the write signal to an analog signal, a write amplifier 327 for driving a writing magnetic head 312, and a phase lock loop (PLL) circuit 328 for generating a clock signal necessary for the operation of the A/D conversion circuit 323 (ADC) or encryption circuit 324 (DEQ).

In the system LSI of the embodiment of FIG. 24, the functions of circuit blocks forming the PRML circuit other than the encryption circuit 324 (DEQ) and the D/A conversion circuits of the encoder/decoder 325 and signal processing circuit 326 can be implemented by the digital signal processor DSP. Further, the automatic gain control type amplifier 321, filter circuit 322, write amplifier 327 and PLL circuit 328 are arranged with use of the variable analog or logic cells of the FPLA.

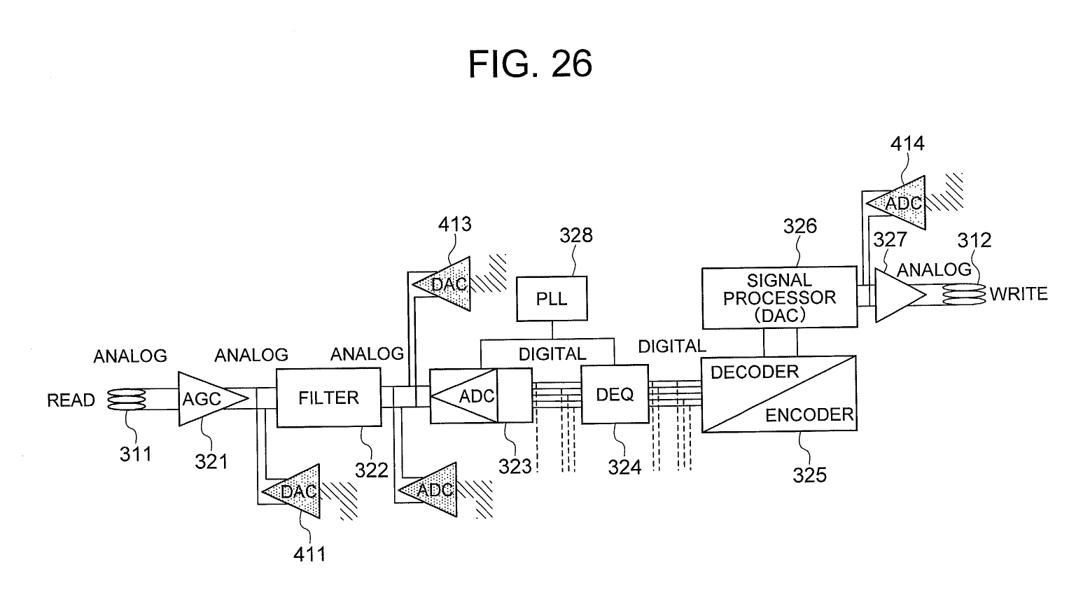

In the system LSI of the present embodiment, furthermore, a D/A conversion circuit 411 for testing the filter circuit 322, a D/A conversion circuit 413 for generating an analog signal for testing an A/D conversion circuit 412 or the A/D conversion circuit 323, a testing A/D conversion circuit 414 for measuring an analog output voltage of the signal processing circuit 326, etc. are arranged with use of the variable analog or logic cells of the FPLA for test as shown in FIG. 26.

As mentioned above, when the present invention is applied, test can be realized even for a small unit circuit formed as a part of the PRML circuit, though test can be realized only for the entire PRML circuit in the prior art. In addition, after test completion, the FPLA used for the test can be used to form the automatic gain control type amplifier 321, write amplifier 327, etc. As a result, the chip can be used wastelessly and thus the chip size can be advantageously reduced.

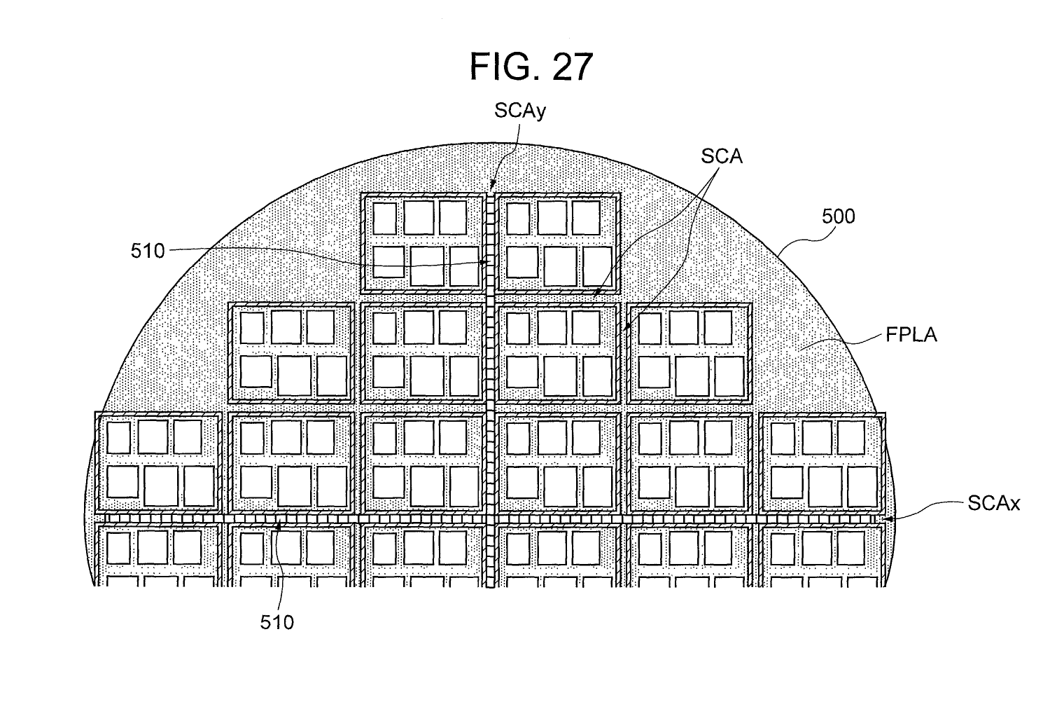

FIG. 27 shows another embodiment of the present invention. In the foregoing embodiment, variable logic cells of the variable logic and analog cells arranged as filled on a single LSI chip except for the zones of circuit blocks are used to form a test circuit and to perform the test over the circuit blocks in the chip. In the embodiment of FIG. 27, on the other hand, variable logic and analog cells are arranged as filled on an entire wafer to form an FPLA on the entire wafer. That is, in the present embodiment, variable logic and analog cells are arranged as filled even in scribe zones SCA at interfaces between LSS's so that variable logic and analog cells remaining in idle spaces between the circuit blocks and between chips are used to form a test circuit and to perform tests for the respective circuits on the wafer.

In the foregoing embodiments, a signal has been input and output to and from the test circuit through pads provided on the respective LSI's. The present embodiment, however, is arranged so that rows of pads 510 for connection with the variable logic cells are provided in the scribe zones SCAx and SCAy passing through nearly centers of the wafer 500 to input and output a signal to and from a test circuit formed by the variable logic cell, though not specifically restricted to this example.

With such an arrangement, the need for provision of pads to the respective LSI's for input and output of a signal to and from the test circuit can be eliminated, the number of pads necessary for each chip can be reduced, a chip size can be reduced, test for the LSI's or for the circuit blocks of the LSI's can be carried out in a burn-in step under a wafer condition, and times for inspection and test of the LSI including an acceleration test can be shortened to a large extent. Further, when test pad is provided for each chip, the total number of pads necessary for the test of LSI's in a wafer condition becomes enormous and it becomes difficult to bring tester probes into contact with all the test pads. In the present embodiment, however, since the test signal is supplied to each chip from the common pads provided in the scribe lines, the number of test pads per wafer can be remarkably reduced and thus test in a wafer condition can be facilitated.

In the embodiment of FIG. 27 enabling the test at the wafer level, decoders 211, 212 or sense amplifier rows 221, 222 provided for each LSI can be provided in the scribe zones SCAx and SCAy, like the test pads. In the embodiment of FIG. 27, further, the test circuit formed by the variable logic and analog cells in the idle spaces may be formed for each LSI, or a single test circuit may be formed for the entire wafer, or a test circuit may be formed for each of four sector zones of the wafer divided by the scribe zones SCAx and SCAy for test as in FIG. 27. Furthermore, test circuits for all the circuit blocks on the chip are arranged as distributed on the wafer for inspection. For example, a CPU test circuit for one part is provided on the wafer, a DSP test circuit is provided for another part, and so on.

Although the invention made by the inventor of the present application has been explained in detail in connection with the embodiments, it goes without saying that the present invention is not limited to the above specific embodiments but may be modified in various ways without departing from the gist or subject matter of the invention. For example, though the test circuit for inspection of the circuit blocks in the chip has been formed in the FPLA of the variable logic and analog cells arranged as filled in the zones other than the zones for formation of the circuit blocks in the foregoing embodiment, the test circuit for inspection of the variable logic cell of the other FPLA can be formed in part of the FPLA for self inspection.

Further, when the FPLA provided in the LSI idle space is utilized, a signal at any position in the chip can be externally extracted or be input thereto. Therefore, upon performing an emulation to perform defect analysis to detect a defective location in a defective LSI or to perform debugging operation over a program developed by the user, such a function as to facilitate the emulation of a monitor circuit which can sample a signal on the bus and can externally monitor a desired internal signal by using variable logic cell so far used as the test circuit can also be realized.

Although the above explanation has been made mainly in connection with the case where the invention made by the inventor of the present application is applied to the system LSI in an application field as its background, the present invention is not limited to this example but may be applied to a general semiconductor integrated circuit having an analog circuit mounted thereon. The present invention is effective when applied to a semiconductor apparatus designed by a CBIC technology.

Effects obtained by typical ones of features of the present invention disclosed by the present application are summarized as follows.

That is, in accordance with the present invention, the test of the analog circuit built in the LSI can be carried out with a relatively high accuracy without using an external tester having a high level of function, and the test circuit for inspecting the analog circuit can be formed on the semiconductor chip while avoiding an increase in the chip size and a reduction in the yield.

In accordance with the present invention, further, the yield of the semiconductor apparatus having the analog circuit therein can be improved, and it can be avoided that the yield is reduced by the defect generation involved by the test circuit itself.

In accordance with the present invention, furthermore, since the analog signal is transmitted in the two-line system of the force and sense lines, the operational accuracy of the semiconductor apparatus can be improved which is arranged to transmit the analog signal between the circuits separated relatively away from each other within the chip.

What is claimed is:

1. A semiconductor apparatus comprising an analog generation circuit including a resistive element, a capacitive element and a switching element for generating a voltage determined by a conduction time of the switching element and by a time constant of the resistive and capacitive elements based on a current flowing through the resistive element controlled by turning ON and OFF of the switching element, wherein an output voltage of the analog generation circuit is transmitted to another circuit or element arranged on a semiconductor chip through a first transmission line, the voltage transmitted to the another circuit or element is fed back to the analog generation circuit through a second transmission line, and the analog generation circuit generates the output voltage according to the fed-back voltage.

2. A semiconductor apparatus as set forth in claim 1, wherein the analog generation circuit can generate an arbitrary voltage according to a pulse width of a signal for control of the switching element.

3. A semiconductor apparatus as set forth in claim 1, wherein the analog generation circuit is a test circuit for generating a voltage for inspection of the another circuit or element arranged on the semiconductor chip.

4. A semiconductor apparatus as set forth in claim 1, wherein the analog generation circuit is a function circuit for taking a role of part of a function of the semiconductor apparatus.

5. A semiconductor apparatus as set forth in claim 1, wherein a plurality of the analog generation circuits are provided in a zone on the semiconductor chip other than zones for formation of circuit blocks, part of the analog generation circuits is formed as a repair circuit for repairing a defect portion present in any of the function circuits taking a role of part of the functions of the semiconductor apparatus.

6. A semiconductor apparatus wherein a variable logic cell and a variable analog cell are provided in a zone on a semiconductor chip other than block formation zones of original function circuits, the variable logic cell including:
a variable logic circuit having memory elements for outputting a logic output in response to an input according to memory information of the memory elements;
variable wiring means having switching elements for connecting and disconnecting a plurality of signal lines for connection of the variable logic circuit with at least another variable logic circuit and signal lines mutually intersected; and
wiring-line connection state memory means for storing states of the switching elements of the variable wiring means, the variable analog cell including:
an analog generation circuit having a resistive element and a capacitive element for generating a voltage determined by a conduction time of the switching elements and by a time constant of the resistive and capacitive elements based on a current flowing through the resistive element controlled by turning ON and OFF operation of the switching elements;
variable wiring means for connecting or disconnecting a plurality of signal lines for connection of the analog generation circuit with at least another variable logic circuit and signal lines mutually intersected; and
wiring-line connection state memory means for storing states of the switching elements of the variable wiring means.

7. A semiconductor apparatus as set forth in claim 6, wherein the variable wiring means and wiring-line connection state memory means in the variable logic and analog cells have identical structures respectively, and the variable logic circuit and the analog generation circuit are formed each by elements selected from an identical group of elements formed on the semiconductor chip.

8. A semiconductor apparatus as set forth in claim 6, wherein the analog generation circuit is arranged to generate a voltage according to a pulse width of a signal for control of the switching elements.

9. A semiconductor apparatus as set forth in claim 6, wherein a circuit for generating the signal for control of the switching elements is formed as the variable logic cell.

10. A semiconductor apparatus as set forth in claim 6, wherein the analog generation circuit forms a test circuit for generating a voltage for inspection of another circuit or element arranged on the semiconductor chip.

11. A semiconductor apparatus as set forth in claim 6, wherein the analog generation circuit is a function circuit for taking a role of part of functions of the semiconductor apparatus.

12. A semiconductor apparatus comprising four memory cells to be alternatively selected according to a combination of signals of positive and negative phases, wherein a variable logic cell and a variable analog cell are provided in a zone on a semiconductor chip other than block formation zones of original function circuits, the variable logic cell including:
a plurality of variable logic cells arranged to outputting signals of positive and negative phases according to memory data of the selected memory cell;
variable wiring means having switching elements for connecting or disconnecting a plurality of signal line pairs for connection of the variable logic circuit with at least another variable logic circuit and signal lines mutually intersected; and
wiring-line connection state memory means for storing states of the switching elements of the variable wiring means,
the variable analog cell including:
an analog generation circuit having a resistive element and a capacitive element for generating a voltage determined by a conduction time of the switching elements and by a time constant of the resistive and capacitive elements based on a current flowing through the resistive element controlled by turning ON and OFF operation of the switching elements;
variable wiring means having switching elements for connecting or disconnecting a plurality of signal line pairs for connection of the analog generation circuit with at least another variable logic circuit and signal lines mutually intersected; and
wiring-line connection state memory means for storing states of the switching elements of the variable wiring means, and
wherein the variable logic cell transmits a signal via the signal lines pairs in a differential system, and the variable analog cell outputs a voltage generated via one of the signal lines in pair and receives a feedback voltage via the other of the signal lines in pair.

13. A semiconductor apparatus as set forth in claim 12, wherein the analog generation circuit is arranged to generate a voltage according to a pulse width of a signal for control of the switching elements.

14. A semiconductor apparatus as set forth in claim 12, wherein a circuit for generating the signal for control of the switching elements is formed as the variable logic cell.

15. A semiconductor apparatus as set forth in claim 12, wherein the analog generation circuit is formed as a test circuit for generating a voltage for inspection of another circuit or element arranged on the semiconductor chip.

16. A semiconductor apparatus as set forth in claim 12, wherein the analog generation circuit is formed as a function circuit for taking a role of part of functions of the semiconductor apparatus.

17. A semiconductor apparatus as set forth in claim 12, wherein a plurality of the analog generation circuits are provided in zones on the semiconductor chip other than zones for formation of circuit blocks, part of the analog generation circuits is formed as a repair circuit for repairing a defective part present in any of the function circuits taking a role of part of the functions of the semiconductor apparatus.

18. A semiconductor apparatus comprising an analog circuit, wherein an output voltage of the analog circuit is transmitted via a first transmission line to another circuit or element arranged on a semiconductor chip, the voltage transmitted to the another circuit or element is fed back to the analog circuit via a second transmission line, and the analog circuit generates the output voltage according to the fed-back voltage.

19. A semiconductor apparatus as set forth in claim 18, wherein the analog circuit is a test circuit for generating a voltage for inspection of another circuit or element arranged on the semiconductor chip.

20. A semiconductor apparatus as set forth in claim 18, wherein the analog circuit is a test circuit for converting to a digital signal an analog signal issued from another analog circuit arranged on the semiconductor chip.

21. A semiconductor apparatus comprising:
an analog generation circuit;
a first transmission line for transmitting an output voltage of the analog generation circuit to another circuit or element arranged on the same semiconductor chip as the analog circuit; and
a second transmission line for feeding the voltage transmitted to the another circuit or element back to the analog generation circuit,
wherein the analog generation circuit generates the output voltage according to the fed-back voltage.

22. A semiconductor apparatus wherein a variable logic cell and a variable analog cell are provided in a zone on a semiconductor chip other than block formation zones of original function circuits,
the variable logic cell including:
a variable logic circuit having memory elements for outputting a logic output in response to an input according to memory information of the memory elements;
variable wiring means having switching elements for connecting or disconnecting a plurality of signal lines for connection of the variable logic circuit with at least another variable logic circuit and signal lines mutually intersected; and
wiring-line connection state memory means for storing states of the switching elements of the variable wiring means,
the variable analog cell including:
an analog generation circuit;
variable wiring means having switching elements for connecting or disconnecting a plurality of signal lines for connection of the analog generation circuit with at least another variable logic circuit and signal lines mutually intersected; and
wiring-line connection state memory means for storing states of the switching elements of the variable wiring means.

23. A semiconductor apparatus comprising four memory cells to be alternatively selected according to a combination of signals of positive and negative phases, wherein a variable logic cell and a variable analog cell are provided in a zone on a semiconductor chip other than block formation zones of original function circuits, the variable logic cell including:
a plurality of variable logic cells arranged to outputting signals of positive and negative phases according to memory data of the selected memory cell;
variable wiring means having switching elements for connecting or disconnecting a plurality of signal lines pairs for connection of the variable logic circuit with at least another variable logic circuit and signal lines mutually intersected; and
wiring-line connection state memory means for storing states of the switching elements of the variable wiring means,
the variable analog cell including:
an analog generation circuit;
variable wiring means having switching elements for connecting or disconnecting a plurality of signal lines for connection of the analog generation circuit with at least another variable logic circuit and signal lines mutually intersected; and
wiring-line connection state memory means for storing states of the switching elements of the variable wiring means, and wherein the variable logic cell transmits a signal via the signal lines pairs in a differential system, and the variable analog cell outputs a voltage generated via one of the signal lines in pair and receives a feedback voltage via the other of the signal lines in pair.
